(19) United States
(12) Patent Application Publication
(10) Pub. No.: US 2022/0180928 A1
(43) Pub. Date: Jun. 9, 2022

(54) STORAGE APPARATUS AND STORAGE CONTROL APPARATUS

(71) Applicant: SONY SEMICONDUCTOR SOLUTIONS CORPORATION, Kanagawa (JP)

(72) Inventor: Haruhiko TERADA, Kanagawa (JP)

(73) Assignee: SONY SEMICONDUCTOR SOLUTIONS CORPORATION, Kanagawa (JP)

(21) Appl. No.: 17/601,153

(22) PCT Filed: Mar. 12, 2020
(86) PCT No.: PCT/JP2020/010772

§ 371 Date: Oct. 4, 2021

(30) Foreign Application Priority Data
Apr. 16, 2019 (JP) 2019-078011

(51) Int. Cl. G11C 13/00

(52) U.S. Cl. CPC G11C 13/0059; G11C 13/0028; G11C 13/0026; G11C 13/0038

(57) ABSTRACT

A storage device that avoids unauthorized access attributable to a snapback when simultaneously accessing a plurality of memory cells includes a plurality of first wires extending in a first direction, a plurality of second wires extending in a second direction, and a plurality of memory cells at a position where any of the plurality of first wires and any of the plurality of second wires intersect each other. A first driving unit supplies a first voltage having any of a positive polarity and a negative polarity or a zero potential to each of the plurality of first wires. A second driving unit supplies a second voltage with a different polarity from the first voltage to any one of the plurality of second wires intersecting a first wire to which the first voltage is supplied and supplies a zero potential to a remainder of the plurality of second wires.

### TECHNICAL FIELD

The present technique relates to a storage apparatus. More specifically, the present technique relates to a storage apparatus that stores data and to a storage control apparatus of the storage apparatus.

### BACKGROUND ART

Conventionally, non-volatile memory devices using resistance random access memories that enable faster data access than flash memories and the like have been garnering attention. For example, techniques for simultaneously writing a same piece of data into a plurality of memory cells in a cross-point type non-volatile semiconductor storage apparatus are being proposed (for example, refer to PTL 1).

### CITATION LIST

### Patent Literature

[PTL 1]

WO 2018/123287

### SUMMARY

### Technical Problem

In the conventional art described above, simultaneous access is performed with respect to a plurality of memory cells. In this case, when a given memory cell is selected and an access current flows, an end-to-end voltage of the memory cell may drop due to a phenomenon referred to as snapback. Therefore, depending on an impedance of a circuit that drives a word line and a bit line, a voltage of any of the lines is inadvertently reduced and may alter an end-to-end voltage of another memory cell connected to the line. At this point, when the end-to-end voltage of the other memory cell reaches a threshold, an access current flows into the memory cell to cause an unauthorized access.

The present technique has been devised in consideration of such circumstances and an object thereof is to avoid an unauthorized access attributable to a snapback when simultaneously accessing a plurality of memory cells.

### Solution to Problem

The present technique has been devised in order to solve the problem described above and a first aspect thereof is a storage apparatus and a storage control apparatus including: a storage unit provided with a plurality of first wires extending in a first direction, a plurality of second wires extending in a second direction that differs from the first direction, and a plurality of memory cells inserted and installed at a position where any of the plurality of first wires and any of the plurality of second wires intersect with each other; a plurality of first driving units configured to supply a first voltage having any of a positive polarity and a negative polarity or a zero potential to each of the plurality of first wires; and a plurality of second driving units configured to supply a second voltage with a different polarity from the first voltage to any one of the plurality of second wires intersecting a first wire to which the first voltage is supplied among the plurality of first wires and configured to supply a zero potential to a remainder of the plurality of second wires intersecting the plurality of first wires. Accordingly, by selecting a memory cell at a position where a first wire supplied with the first voltage and a second wire supplied with the second voltage intersect each other and supplying a zero potential to second wires connected to memory cells which have not been selected and which are connected to the first wire and to first wires only connected to memory cells which are not selected, an effect can be produced in that an independent current pathway is secured with respect to the selected memory cell without sacrificing an operation margin.

In addition, in the first aspect, the plurality of first driving units may be provided for each of the plurality of memory cells which share one of the plurality of first wires, and the plurality of second driving units may be provided for each of the plurality of memory cells which share one of the plurality of second wires. Accordingly, an effect can be produced in that wires are driven for each of a plurality of memory cells.

Furthermore, in the first aspect, when dividing the plurality of first driving units and the plurality of second driving units into a plurality of unit structures provided with a predetermined number of the plurality of first driving units and a predetermined number of the plurality of second driving units, voltage supply patterns with respect to the pluralities of the first and second wires may differ from each other between adjacent unit structures among the plurality of unit structures. Accordingly, an effect can be produced in that a voltage is supplied in a consistent manner in an entire structure that combines the unit structures.

In addition, in the first aspect, the pluralities of first and second driving units at a boundary between adjacent unit structures among the plurality of unit structures may be shared by the adjacent unit structures. Accordingly, an effect can be produced in that a voltage is supplied in a consistent manner even to wires that straddle unit structures.

Furthermore, in the first aspect, the plurality of memory cells may be provided with storage elements of which each assume any resistance state of first and second resistance states, and the storage elements may be set to any of the first and second resistance states in accordance with a direction of a current that flows when voltages of mutually different polarities are applied to the first and second wires. Accordingly, an effect can be produced in that an independent current pathway is secured with respect to a memory cell that utilizes a resistance random access memory.

In addition, in the first aspect, the plurality of memory cells may be provided with first and second storage elements which share one of the plurality of first wires. Accordingly, an effect can be produced in that, in a structure in which memory cells are stacked in two layers, an independent current pathway is secured with respect to a selected memory cell. In this case, the plurality of second driving units may be configured to supply a voltage of a zero potential to the second wire of one of the first and second storage elements and to supply a voltage having one of a positive polarity and a negative polarity to the second wire of the other storage element. Accordingly, an effect can be produced in that only one of the memory cells being stacked in two layers is selected.

Furthermore, in the first aspect, the storage apparatus may further include a plurality of sense amplifiers connected to the plurality of second wires so as to correspond to each of the plurality of second driving units. Accordingly, an effect can be produced in that sense amplifiers are connected to the second wires with a small parasitic capacitance.

In addition, in the first aspect, the storage apparatus may further include a control circuit configured to supply a control signal for instructing a polarity of a voltage to be applied to the pluralities of first and second wires to the pluralities of first and second driving units. Accordingly, an effect can be produced in that, by causing the first and second driving units to supply a voltage in accordance with an instruction from the control circuit, an independent current pathway is secured with respect to a selected memory cell without sacrificing an operation margin.

### BRIEF DESCRIPTION OF DRAWINGS

FIG. 1 is a diagram showing an overall configuration example of a storage apparatus 300 according to an embodiment of the present technique.

FIG. 2 is a diagram showing a configuration example of a resistance random access memory cell 10 according to the embodiment of the present technique.

FIG. 3 is a diagram schematically representing a distribution example of resistance values of the resistance random access memory cell 10 according to the embodiment of the present technique.

FIG. 4 is a diagram showing a configuration example of sub-tiles in a memory bank 310 according to the embodiment of the present technique.

FIG. 5 is a diagram showing a configuration example of tiles in the memory bank 310 according to the embodiment of the present technique.

FIG. 6 is a diagram showing a notation example of an upper-layer memory cell 111 and a lower-layer memory cell 112 according to the embodiment of the present technique.

FIG. 7 is a diagram showing a notation example of a tile 320 according to the embodiment of the present technique.

FIG. 8 is a diagram showing an example of a voltage applied to the upper-layer memory cell 111 and the lower-layer memory cell 112 according to the embodiment of the present technique.

FIG. 9 is a diagram showing a circuit arrangement example of the memory bank 310 according to the embodiment of the present technique.

FIG. 10 is a diagram showing a circuit arrangement example of memory dies of the storage apparatus 300 according to the embodiment of the present technique.

FIG. 11 is a diagram showing a first pattern example (a pattern UA) of applied voltage during a set operation or a sense operation of the upper-layer memory cell 111 according to a first embodiment of the present technique.

FIG. 12 is a diagram showing a second pattern example (a pattern UB) of applied voltage during a set operation or a sense operation of the upper-layer memory cell 111 according to the first embodiment of the present technique.

FIG. 13 is a diagram showing a third pattern example (a pattern UC) of applied voltage during a set operation or a sense operation of the upper-layer memory cell 111 according to the first embodiment of the present technique.

FIG. 14 is a diagram showing a fourth pattern example (a pattern UD) of applied voltage during a set operation or a sense operation of the upper-layer memory cell 111 according to the first embodiment of the present technique.

FIG. 15 is a diagram showing a fifth pattern example (a pattern UE) of applied voltage during a set operation or a sense operation of the upper-layer memory cell 111 according to the first embodiment of the present technique.

FIG. 16 is a diagram showing a sixth pattern example (a pattern UF) of applied voltage during a set operation or a sense operation of the upper-layer memory cell 111 according to the first embodiment of the present technique.

FIG. 17 is a diagram showing a seventh pattern example (a pattern UG) of applied voltage during a set operation or a sense operation of the upper-layer memory cell 111 according to the first embodiment of the present technique.

FIG. 18 is a diagram showing an eighth pattern example (a pattern UH) of applied voltage during a set operation or a sense operation of the upper-layer memory cell 111 according to the first embodiment of the present technique.

FIG. 19 is a diagram showing a first pattern example (a pattern LA) of applied voltage during a set operation or a sense operation of the lower-layer memory cell 112 according to the first embodiment of the present technique.

FIG. 20 is a diagram showing a second pattern example (a pattern LB) of applied voltage during a set operation or a sense operation of the lower-layer memory cell 112 according to the first embodiment of the present technique.

FIG. 21 is a diagram showing a third pattern example (a pattern LC) of applied voltage during a set operation or a sense operation of the lower-layer memory cell 112 according to the first embodiment of the present technique.

FIG. 22 is a diagram showing a fourth pattern example (a pattern LD) of applied voltage during a set operation or a sense operation of the lower-layer memory cell 112 according to the first embodiment of the present technique.

FIG. 23 is a diagram showing a fifth pattern example (a pattern LE) of applied voltage during a set operation or a sense operation of the lower-layer memory cell 112 according to the first embodiment of the present technique.

FIG. 24 is a diagram showing a sixth pattern example (a pattern LF) of applied voltage during a set operation or a sense operation of the lower-layer memory cell 112 according to the first embodiment of the present technique.

FIG. 25 is a diagram showing a seventh pattern example (a pattern LG) of applied voltage during a set operation or a sense operation of the lower-layer memory cell 112 according to the first embodiment of the present technique.

FIG. 26 is a diagram showing an eighth pattern example (a pattern LED of applied voltage during a set operation or a sense operation of the lower-layer memory cell 112 according to the first embodiment of the present technique.

FIG. 27 is a diagram showing the first pattern example (the pattern UA) of applied voltage during a reset operation of the upper-layer memory cell 111 according to the first embodiment of the present technique.

FIG. 28 is a diagram showing the second pattern example (the pattern UB) of applied voltage during a reset operation of the upper-layer memory cell 111 according to the first embodiment of the present technique.

FIG. 29 is a diagram showing the third pattern example (the pattern UC) of applied voltage during a reset operation of the upper-layer memory cell 111 according to the first embodiment of the present technique.

FIG. 30 is a diagram showing the fourth pattern example (the pattern UD) of applied voltage during a reset operation of the upper-layer memory cell 111 according to the first embodiment of the present technique.

FIG. 31 is a diagram showing the fifth pattern example (the pattern UE) of applied voltage during a reset operation of the upper-layer memory cell 111 according to the first embodiment of the present technique.

FIG. 32 is a diagram showing the sixth pattern example (the pattern UF) of applied voltage during a reset operation of the upper-layer memory cell 111 according to the first embodiment of the present technique.

FIG. 33 is a diagram showing the seventh pattern example (the pattern UG) of applied voltage during a reset operation of the upper-layer memory cell 111 according to the first embodiment of the present technique.

FIG. 34 is a diagram showing the eighth pattern example (the pattern UH) of applied voltage during a reset operation of the upper-layer memory cell 111 according to the first embodiment of the present technique.

FIG. 35 is a diagram showing the first pattern example (the pattern LA) of applied voltage during a reset operation of the lower-layer memory cell 112 according to the first embodiment of the present technique.

FIG. 36 is a diagram showing the second pattern example (the pattern LB) of applied voltage during a reset operation of the lower-layer memory cell 112 according to the first embodiment of the present technique.

FIG. 37 is a diagram showing the third pattern example (the pattern LC) of applied voltage during a reset operation of the lower-layer memory cell 112 according to the first embodiment of the present technique.

FIG. 38 is a diagram showing the fourth pattern example (the pattern LD) of applied voltage during a reset operation of the lower-layer memory cell 112 according to the first embodiment of the present technique.

FIG. 39 is a diagram showing the fifth pattern example (the pattern LE) of applied voltage during a reset operation of the lower-layer memory cell 112 according to the first embodiment of the present technique.

FIG. 40 is a diagram showing the sixth pattern example (the pattern LF) of applied voltage during a reset operation of the lower-layer memory cell 112 according to the first embodiment of the present technique.

FIG. 41 is a diagram showing the seventh pattern example (the pattern LG) of applied voltage during a reset operation of the lower-layer memory cell 112 according to the first embodiment of the present technique.

FIG. 42 is a diagram showing the eighth pattern example (the pattern LH) of applied voltage during a reset operation of the lower-layer memory cell 112 according to the first embodiment of the present technique.

FIG. 43 is a diagram showing an arrangement example of patterns of applied voltage according to the embodiment of the present technique.

FIG. 44 is a diagram showing combination examples of arrangements of patterns of applied voltage according to the embodiment of the present technique.

FIG. 45 is a diagram showing a configuration example of a bank control circuit 390 according to the embodiment of the present technique.

FIG. 46 is a diagram showing an arrangement example of address lines for supplying an address signal from the bank control circuit 390 according to the embodiment of the present technique.

FIG. 47 is a diagram showing an example of names of address signals supplied from the bank control circuit 390 according to the embodiment of the present technique.

FIG. 48 is a diagram showing an example of contents of address signals supplied from the bank control circuit 390 according to the embodiment of the present technique.

FIG. 49 is a diagram showing an arrangement example of a sense amplifier 290 according to the embodiment of the present technique.

FIG. 50 is a diagram showing a first pattern example (a pattern XA) of applied voltage during a set operation or a sense operation according to a second embodiment of the present technique.

FIG. 51 is a diagram showing a second pattern example (a pattern XB) of applied voltage during a set operation or a sense operation according to the second embodiment of the present technique.

### DESCRIPTION OF EMBODIMENTS

Hereinafter, modes (hereinafter, referred to as embodiments) for implementing the present technique will be described. The description will be given in the following order.

1. First embodiment (example of application to two-layer cross point memory)
2. Second embodiment (example of application to single-layer cross point memory)
3. Modifications (configurations with three or more layers)

### 1. FIRST EMBODIMENT

[Overall Configuration of Storage Apparatus]

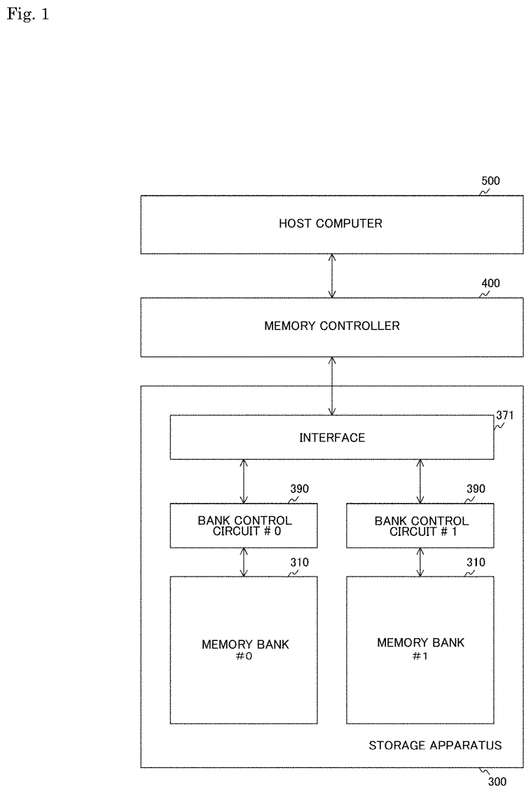

FIG. 1 is a diagram showing an overall configuration example of a storage apparatus 300 according to an embodiment of the present technique.

The storage apparatus 300 has, for example, a two-bank configuration and is provided with memory banks 310 and bank control circuits 390. Each of the memory banks 310 is provided with a memory array in which resistance random access memory cells are arranged in a matrix pattern. Each bank control circuit 390 is provided so as to correspond to each memory bank 310 and controls access to the corresponding memory bank 310.

In addition, the storage apparatus 300 is provided with an interface 371 between the storage apparatus 300 and a memory controller 400. A host computer 500 is connected to the memory controller 400, and an access command is issued to the storage apparatus 300 from the host computer 500 via the memory controller 400. The interface 371 communicates with the memory controller 400 and mediates the bank control circuit 390 of each bank.

[Resistance Random Access Memory Cell]

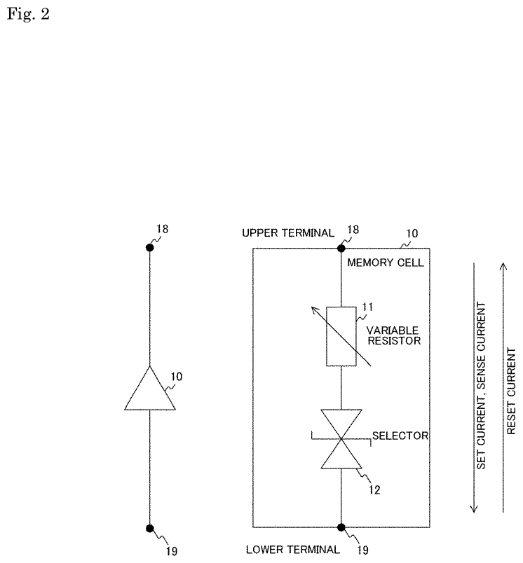

FIG. 2 is a diagram showing a configuration example of a resistance random access memory cell 10 according to the embodiment of the present technique.

The memory cell 10 has a series structure of a variable resistor 11 and a selector 12. The variable resistor 11 is an element of which a resistance state reversibly changes in accordance with a potential difference between voltages applied to both ends thereof. The selector 12 is an element with bidirectional diode characteristics, and the selector 12 enters a conductive (on) state when an absolute value of a potential difference between voltages applied to both ends thereof is larger than a prescribed potential difference but enters a non-conductive (off) state when the absolute value of the potential difference between the voltages applied to both ends thereof is smaller than the prescribed potential difference.

The memory cell 10 is provided with an upper terminal 18 connected to the variable resistor 11 and a lower terminal 19 connected to the selector 12. When a current flows from the upper terminal 18 to the lower terminal 19 in a conductive state of the selector 12, a set operation or a sense operation is performed in accordance with a voltage between both ends of the variable resistor 11. On the other hand, when a current flows from the lower terminal 19 to the upper terminal 18, a reset operation is performed in accordance with the voltage between both ends of the variable resistor 11.

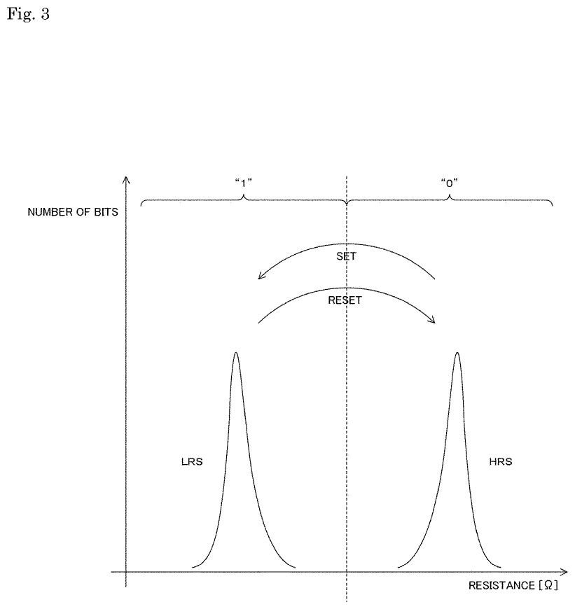

FIG. 3 is a diagram schematically representing a distribution example of resistance values of the resistance random access memory cell 10 according to the embodiment of the present technique. In the diagram, an abscissa indicates a distribution of resistance and an ordinate indicates a distribution of the number of bits.

The variable resistor 11 may assume any resistance state of a high resistance state (HRS) and a low resistance state (LRS). In this example, the high resistance state HRS is associated with data “0” and the low resistance state LRS is associated with data “1”. In other words, the variable resistor 11 functions as a storage element that stores 1-bit data.

An operation of changing the resistance state of the variable resistor 11 from the high resistance state HRS to the low resistance state LRS will be referred to as a set operation and an operation of changing the resistance state from the low resistance state LRS to the high resistance state HRS will be referred to as a reset operation. In addition, an operation of reading the resistance state of the variable resistor 11 will be referred to as a sense operation.

[Sub-tile]

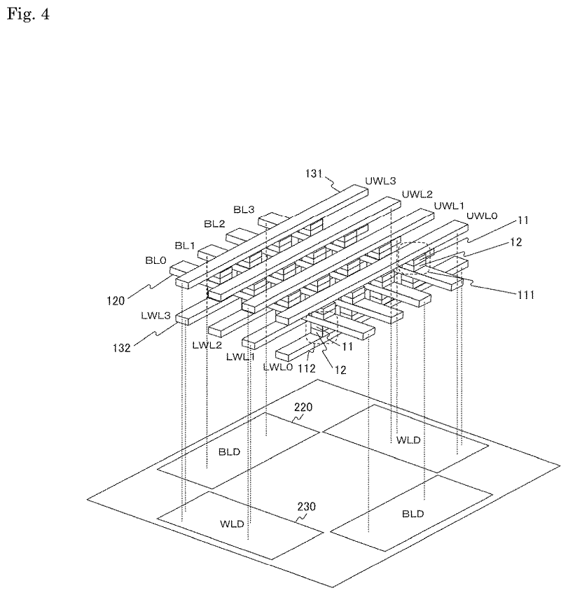

FIG. 4 is a diagram showing a configuration example of sub-tiles in the memory bank 310 according to the embodiment of the present technique.

In the present embodiment, a two-layer cross point memory provided with a two-layer memory array in which a memory array constituted by the memory cells 10 described above is stacked in two layers will be assumed. In an upper-layer memory cell 111, an upper word line (UWL) 131 is connected to the upper terminal 18 on a side of the variable resistor 11 and a bit line (BL) 120 is connected to the lower terminal 19 on a side of the selector 12. On the other hand, in a lower-layer memory cell 112, the bit line 120 is connected to the upper terminal 18 on the side of the variable resistor 11 and a lower word line (LWL) 132 is connected to the lower terminal 19 on the side of the selector 12.

In this manner, both the upper-layer memory cell 111 and the lower-layer memory cell 112 are provided with the variable resistor 11 on an upper side and the selector 12 on a lower side. Accordingly, manufacturing can be facilitated and characteristics of the two layers can be made uniform.

In addition, in this structure, the bit line 120 is shared by the upper-layer memory cell 111 and the lower-layer memory cell 112. Accordingly, manufacturing can be facilitated and peripheral circuit components can be reduced.

In this example, four bit lines 120 extend in a first direction and four upper word lines 131 and lower word lines 132 extend in a second direction. For example, it is conceivable that, on a plane of a memory array, the first direction in which the bit lines 120 extend is adopted as a vertical direction and the second direction in which the upper word lines 131 and the lower word lines 132 extend is adopted as a horizontal direction.

A total of 16 upper-layer memory cells 111 are inserted and installed at positions where the four upper word lines 131 and the four bit lines 120 intersect with each other. In addition, a total of 16 lower-layer memory cells 112 are inserted and installed at positions where the four bit lines 120 and the four lower word lines 132 intersect with each other. In other words, in this manner, a cross point memory constituted by memory arrays in two layers is constructed.

A bit line decoder (BLD) 220 and a word line decoder (WLD) 230 are arranged on a substrate surface on a lower side of the memory arrays. The bit line decoder 220 applies a voltage to the bit lines 120 according to an instruction from the bank control circuit 390. The word line decoder 230 applies a voltage to the upper word lines 131 and the lower word lines 132 according to an instruction from the bank control circuit 390. In this example, the bit lines 120 and the bit line decoder 220 are connected to each other between two opposing sides among four sides of a memory array and the upper word lines 131 and the lower word lines 132 and the word line decoder 230 are connected to each other between the other two sides.

A structure made up of the four bit lines 120, the four upper word lines 131, the four lower word lines 132, the 16 upper-layer memory cells 111, the 16 lower-layer memory cells 112, the bit line decoder 220, and the word line decoder 230 will be referred to as a sub-tile.

[Tile]

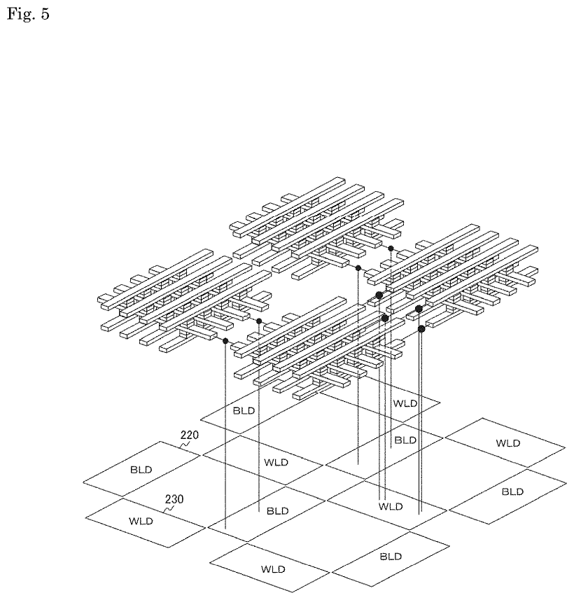

FIG. 5 is a diagram showing a configuration example of tiles in the memory bank 310 according to the embodiment of the present technique.

A structure in which a total of four sub-tiles described above are arranged on a plane in a two-by-two pattern will be referred to as a tile. In this case, the bit line decoder 220 and the word line decoder 230 are shared between adjacent sub-tiles.

[Notation]

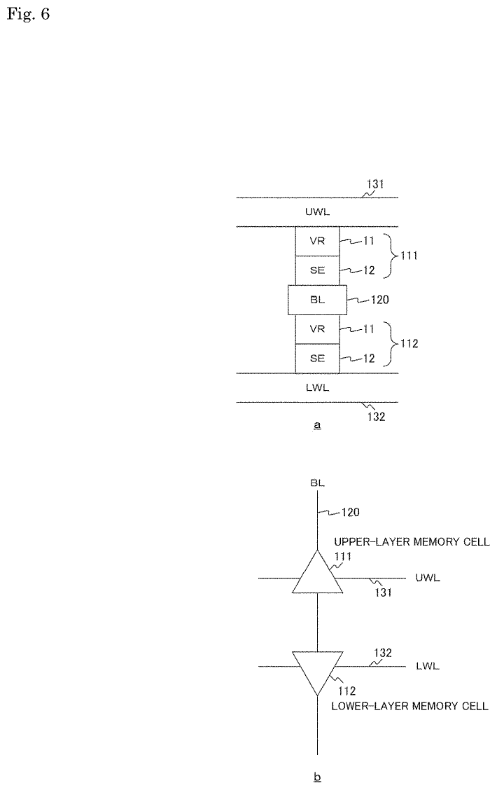

FIG. 6 is a diagram showing a notation example of the upper-layer memory cell 111 and the lower-layer memory cell 112 according to the embodiment of the present technique.

In the memory array according to the present embodiment, as shown in a sectional view in “a” in FIG. 6, the upper-layer memory cell 111 connects to the upper word line 131 and the bit line 120 and the lower-layer memory cell 112 connects to the bit line 120 and the lower word line 132. In the sectional view, the bit lines 120 extend in a rearward direction from the front.

Therefore, hereinafter, a relationship among the upper-layer memory cell 111 and the lower-layer memory cell 112, the bit lines 120, and the upper word lines 131 and the lower word lines 132 will be notated as shown in “b” in FIG. 6.

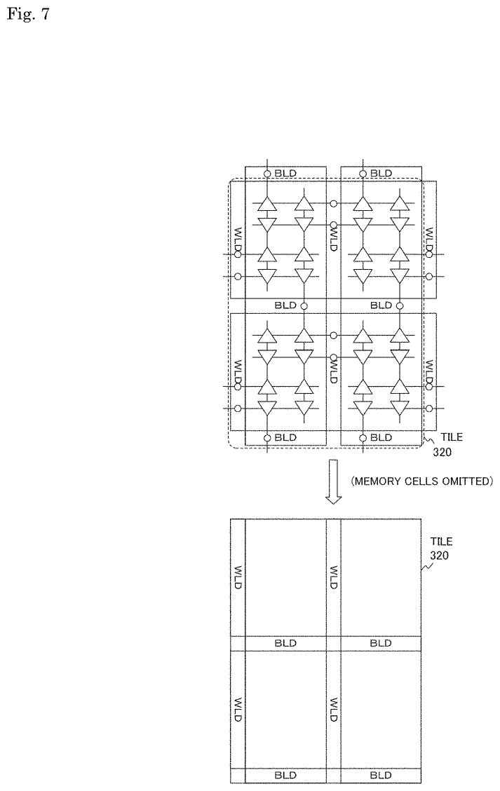

FIG. 7 is a diagram showing a notation example of a tile 320 according to the embodiment of the present technique.

Using the notation described above, the tile 320 can be expressed on a plane as shown in FIG. 7. However, since the bit lines 120, the upper word lines 131, and the lower word lines 132 at an edge of the tile 320 and the bit line decoder 220 and the word line decoder 230 are to be shared between adjacent tiles, boundaries must be defined. In consideration thereof, in this case, the word line decoder 230 of a left side and the bit line decoder 220 of a lower side are assumed to belong to the tile 320 and the word line decoder 230 of a right side and the bit line decoder 220 of an upper side are assumed to belong to the adjacent tile 320.

[Voltage]

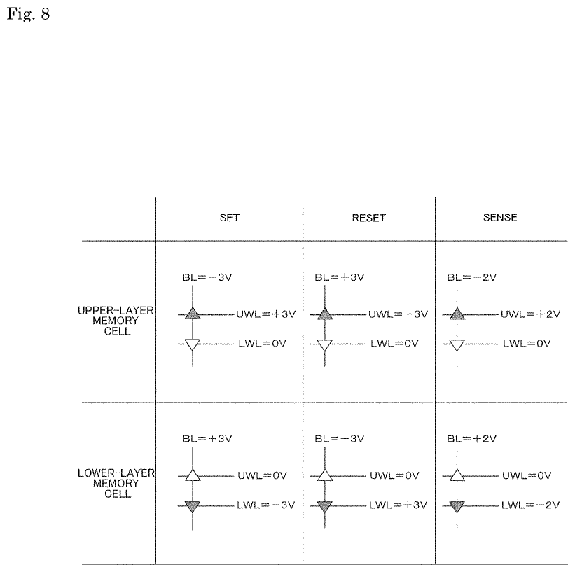

FIG. 8 is a diagram showing an example of a voltage applied to the upper-layer memory cell 111 and the lower-layer memory cell 112 according to the embodiment of the present technique.

As described earlier, the upper word line 131 is connected to the side of the variable resistor 11 in the upper-layer memory cell 111 and the bit line 120 is connected to the side of the variable resistor 11 in the lower-layer memory cell 112. Therefore, polarities of voltages applied between the bit line 120 and the upper word line 131 and the lower word line 132 differ between the upper-layer memory cell 111 and the lower-layer memory cell 112.

In other words, in a set operation, in the upper-layer memory cell 111, for example, −3 V is applied to the bit line 120 and, for example, +3 V is applied to the upper word line 131. On the other hand, polarities are reversed in the lower-layer memory cell 112 and, for example, +3 V is applied to the bit line 120 and, for example, −3 V is applied to the lower word line 132.

In addition, in a reset operation, polarities are reversed from the set operation described above and in the upper-layer memory cell 111, for example, +3 V is applied to the bit line 120 and, for example, −3 V is applied to the upper word line 131. On the other hand, polarities are reversed in the lower-layer memory cell 112 and, for example, −3 V is applied to the bit line 120 and, for example, +3 V is applied to the lower word line 132.

In addition, in a sense operation, potential differences are reduced in the same polarities as the set operation described above. In other words, in the upper-layer memory cell 111, for example, −2 V is applied to the bit line 120 and, for example, +2 V is applied to the upper word line 131. On the other hand, polarities are reversed in the lower-layer memory cell 112 and, for example, +2 V is applied to the bit line 120 and, for example, −2 V is applied to the lower word line 132.

It should be noted that values of potentials described above are merely examples and can be appropriately set in accordance with characteristics of the memory cells 10.

[Bank]

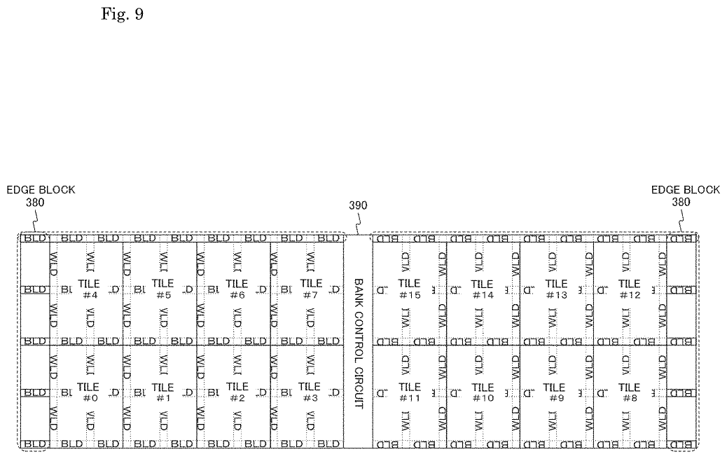

FIG. 9 is a diagram showing a circuit arrangement example of the memory bank 310 according to the embodiment of the present technique. In this example, a total of 16 tiles are arranged to the left and right of the bank control circuit 390, with each eight tiles arranged in two rows and four columns constituting the memory bank 310.

As described above, parts of the bit lines 120, the upper word lines 131, and the lower word lines 132 at edges of tiles, the bit line decoder 220, and the word line decoder 230 belong to an adjacent tile. In this case, a bit line decoder 220 that does not belong to any tile is required at an edge of the memory bank 310. A structure including the bit line decoder 220 that does not belong to any tile will be referred to as an edge block 380.

[Memory Die]

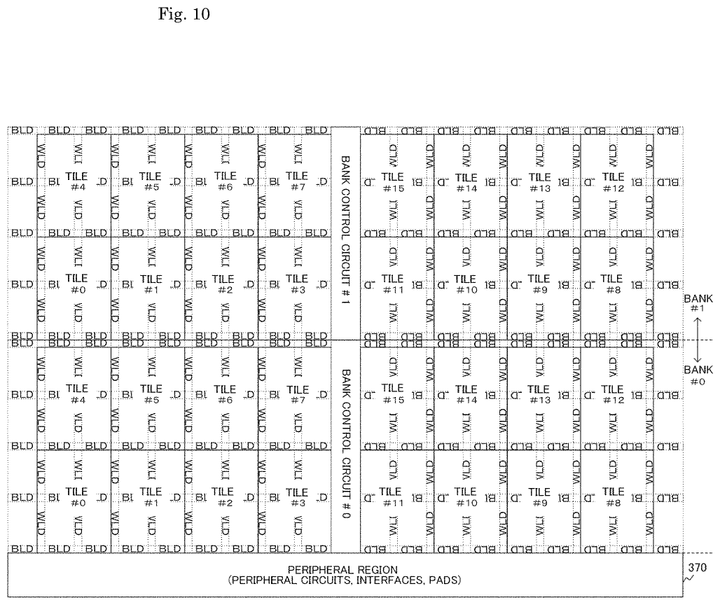

FIG. 10 is a diagram showing a circuit arrangement example of memory dies of the storage apparatus 300 according to the embodiment of the present technique.

In this example, two memory banks #0 and #1 are provided. In other words, this is a configuration in which two of the circuit arrangement example of the memory bank 310 described above are independently arranged side by side.

In addition, in this example, a peripheral region 370 is provided. The interface 371 described earlier is included in the peripheral region 370. Furthermore, the peripheral region 370 includes other peripheral circuits, pads, and the like.

[Voltage Application Pattern]

Hereinafter, a pattern of voltage applied to each tile will be described separately for during a set operation or a sense operation and during a reset operation. In the following diagram, a white circle “∘” indicates a zero potential, “+” indicates a positive potential, and “−” indicates a negative potential. As described above, the positive potential is +3 V and the negative potential is −3 V during a set operation and a reset operation. In addition, the positive potential is +2 V and the negative potential is −2 V during a sense operation.

In addition, the 16 upper-layer memory cells 111 in a tile are distinguished as memory cells U0 to U15 and the 16 lower-layer memory cells 112 in the tile are distinguished as memory cells L0 to L15. Furthermore, the upper word lines 131 and the lower word lines 132 in a tile and straddling tiles are distinguished as word lines w0 to w11 and the bit lines 120 in the tile and straddling tiles are distinguished as bit lines b0 to b5.

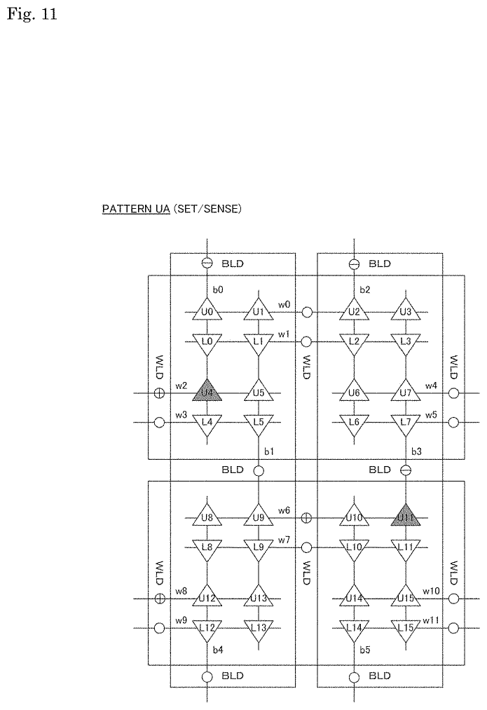

FIG. 11 is a diagram showing a first pattern example (a pattern UA) of applied voltage during a set operation or a sense operation of the upper-layer memory cell 111 according to a first embodiment of the present technique.

In the pattern UA, a zero potential is applied to the bit lines b1, b4, and b5 and a negative potential is applied to the bit lines b0, b2, and b3. In addition, a zero potential is applied to the word lines w0, w1, w3, w4, w5, w7, w9, w10, and w11 and a positive potential is applied to the word lines w2, w6, and w8.

Accordingly, the two memory cells, U4 and U11, are simultaneously selected and a set operation or a sense operation is performed. At this point, since each current pathway is independent and a zero potential is applied to at least one of bit lines and word lines of unselected memory cells, there is no effect due to a snapback.

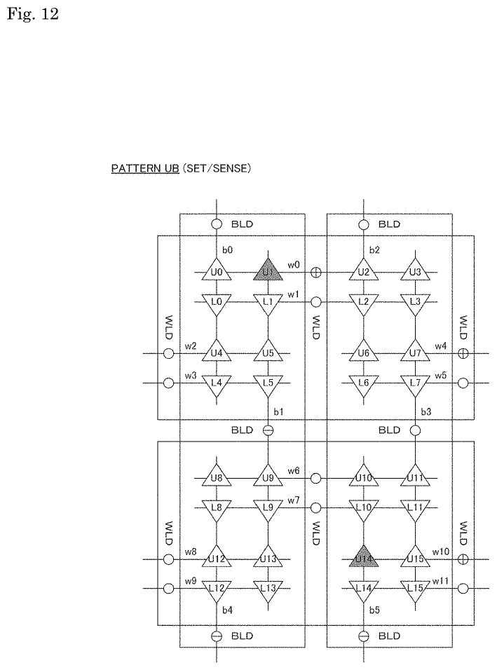

FIG. 12 is a diagram showing a second pattern example (a pattern UB) of applied voltage during a set operation or a sense operation of the upper-layer memory cell 111 according to the first embodiment of the present technique.

In the pattern UB, a zero potential is applied to the bit lines b0, b2, and b3 and a negative potential is applied to the bit lines b1, b4, and b5. In addition, a zero potential is applied to the word lines w1, w2, w3, w5, w6, w7, w8, w9, and w11 and a positive potential is applied to the word lines w0, w4, and w10.

Accordingly, the two memory cells, U1 and U14, are simultaneously selected and a set operation or a sense operation is performed. At this point, since each current pathway is independent and a zero potential is applied to at least one of bit lines and word lines of unselected memory cells, there is no effect due to a snapback.

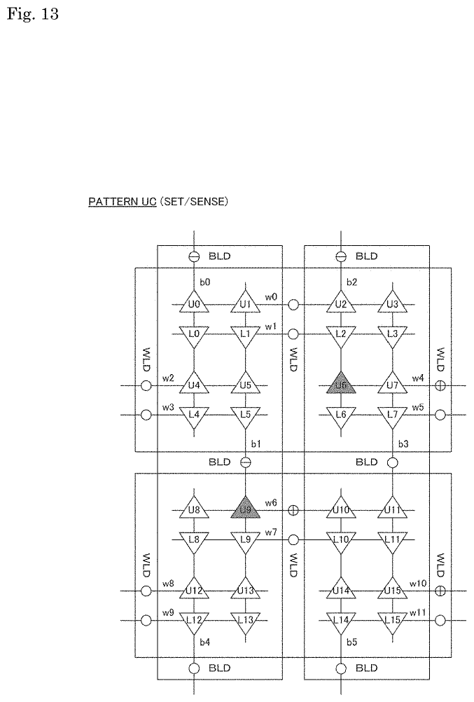

FIG. 13 is a diagram showing a third pattern example (a pattern UC) of applied voltage during a set operation or a sense operation of the upper-layer memory cell 111 according to the first embodiment of the present technique.

In the pattern UC, a zero potential is applied to the bit lines b3, b4, and b5 and a negative potential is applied to the bit lines b0, b1, and b2. In addition, a zero potential is applied to the word lines w0, w1, w2, w3, w5, w7, w8, w9, and w11 and a positive potential is applied to the word lines w4, w6, and w10.

Accordingly, the two memory cells, U6 and U9, are simultaneously selected and a set operation or a sense operation is performed. At this point, since each current pathway is independent and a zero potential is applied to at least one of bit lines and word lines of unselected memory cells, there is no effect due to a snapback.

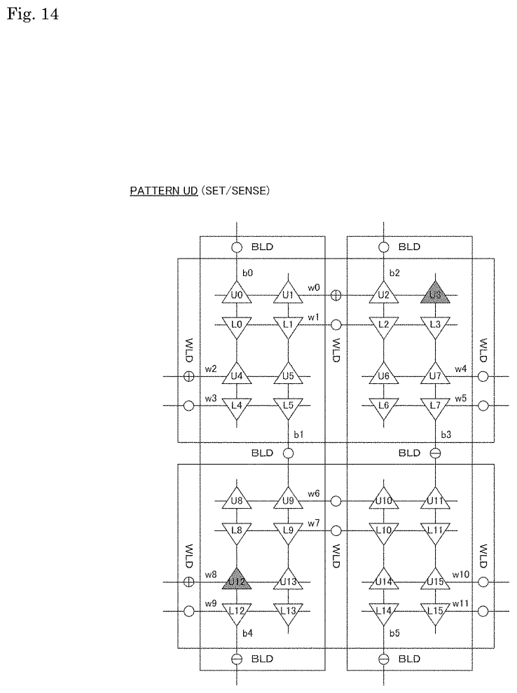

FIG. 14 is a diagram showing a fourth pattern example (a pattern UD) of applied voltage during a set operation or a sense operation of the upper-layer memory cell 111 according to the first embodiment of the present technique.

In the pattern UD, a zero potential is applied to the bit lines b0, b1, and b2 and a negative potential is applied to the bit lines b3, b4, and b5. In addition, a zero potential is applied to the word lines w1, w3, w4, w5, w6, w7, w9, w10, and w11 and a positive potential is applied to the word lines w1, w2, and w8.

Accordingly, the two memory cells, U3 and U12, are simultaneously selected and a set operation or a sense operation is performed. At this point, since each current pathway is independent and a zero potential is applied to at least one of bit lines and word lines of unselected memory cells, there is no effect due to a snapback.

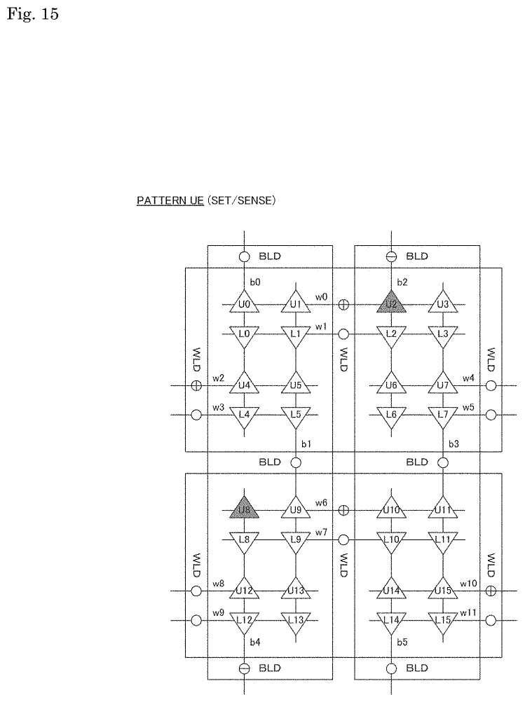

FIG. 15 is a diagram showing a fifth pattern example (a pattern UE) of applied voltage during a set operation or a sense operation of the upper-layer memory cell 111 according to the first embodiment of the present technique.

In the pattern UE, a zero potential is applied to the bit lines b0, b1, b3, and b5 and a negative potential is applied to the bit lines b2 and b4. In addition, a zero potential is applied to the word lines w1, w3, w4, w5, w7, w8, w9, and w11 and a positive potential is applied to the word lines w0, w2, w6, and w10.

Accordingly, the two memory cells, U2 and U8, are simultaneously selected and a set operation or a sense operation is performed. At this point, since each current pathway is independent and a zero potential is applied to at least one of bit lines and word lines of unselected memory cells, there is no effect due to a snapback.

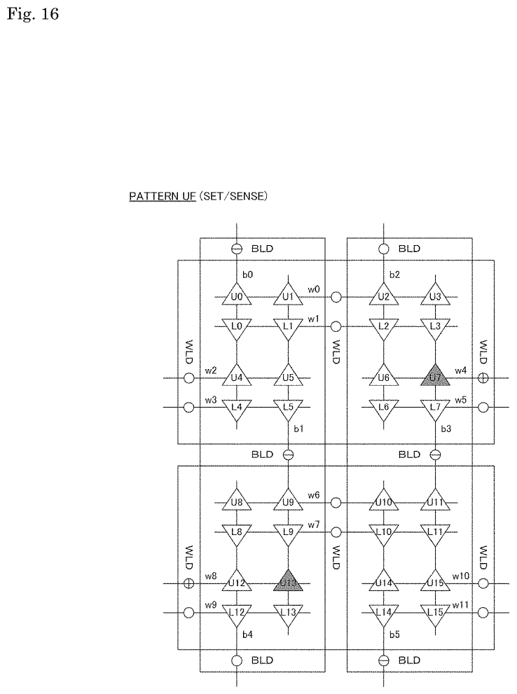

FIG. 16 is a diagram showing a sixth pattern example (a pattern UF) of applied voltage during a set operation or a sense operation of the upper-layer memory cell 111 according to the first embodiment of the present technique.

In the pattern UF, a zero potential is applied to the bit lines b2 and b4 and a negative potential is applied to the bit lines b0, b1, b3, and b5. In addition, a zero potential is applied to the word lines w0, w1, w2, w3, w5, w6, w7, w9, w10, and w11 and a positive potential is applied to the word lines w4 and w8.

Accordingly, the two memory cells, U7 and U13, are simultaneously selected and a set operation or a sense operation is performed. At this point, since each current pathway is independent and a zero potential is applied to at least one of bit lines and word lines of unselected memory cells, there is no effect due to a snapback.

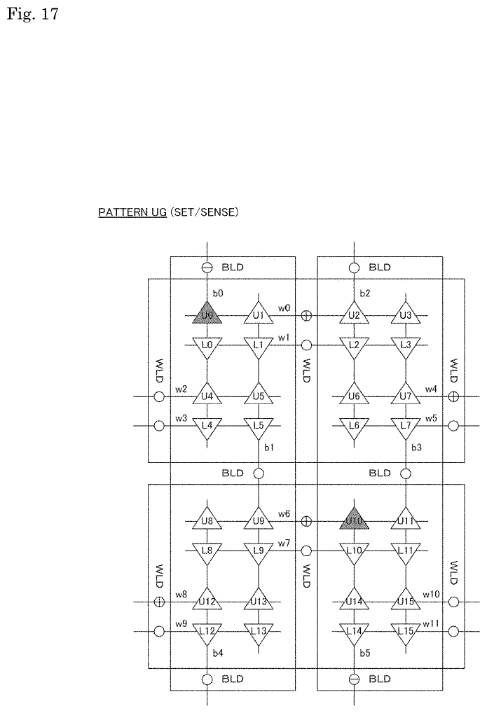

FIG. 17 is a diagram showing a seventh pattern example (a pattern UG) of applied voltage during a set operation or a sense operation of the upper-layer memory cell 111 according to the first embodiment of the present technique.

In the pattern UG, a zero potential is applied to the bit lines b1, b2, b3, and b4 and a negative potential is applied to the bit lines b0 and b5. In addition, a zero potential is applied to the word lines w1, w2, w3, w5, w7, w9, w10, and w11 and a positive potential is applied to the word lines w0, w4, w6, and w8.

Accordingly, the two memory cells, U0 and U10, are simultaneously selected and a set operation or a sense operation is performed. At this point, since each current pathway is independent and a zero potential is applied to at least one of bit lines and word lines of unselected memory cells, there is no effect due to a snapback.

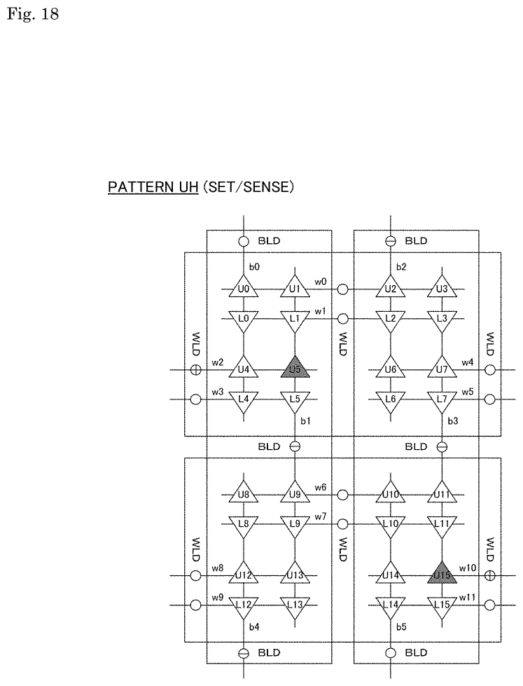

FIG. 18 is a diagram showing an eighth pattern example (a pattern UH) of applied voltage during a set operation or a sense operation of the upper-layer memory cell 111 according to the first embodiment of the present technique.

In the pattern UH, a zero potential is applied to the bit lines b0 and b5 and a negative potential is applied to the bit lines b1, b2, b3, and b4. In addition, a zero potential is applied to the word lines w0, w1, w3, w4, w5, w6, w7, w8, w9, and w11 and a positive potential is applied to the word lines w2 and w10.

Accordingly, the two memory cells, U5 and U15, are simultaneously selected and a set operation or a sense operation is performed. At this point, since each current pathway is independent and a zero potential is applied to at least one of bit lines and word lines of unselected memory cells, there is no effect due to a snapback.

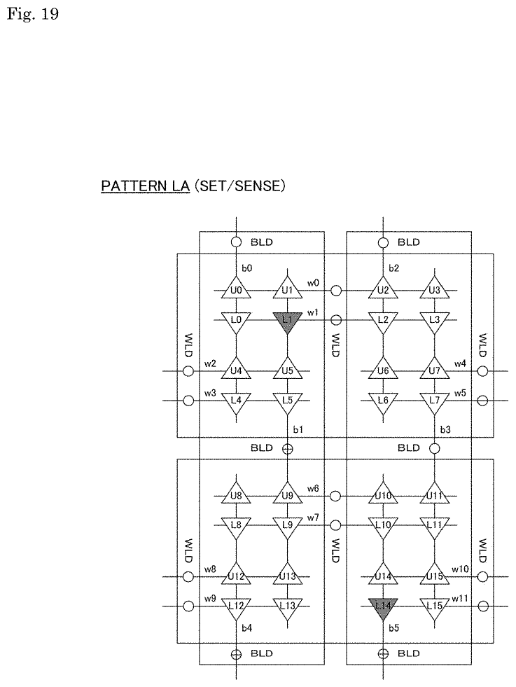

FIG. 19 is a diagram showing a first pattern example (a pattern LA) of applied voltage during a set operation or a sense operation of the lower-layer memory cell 112 according to the first embodiment of the present technique.

In the pattern LA, a zero potential is applied to the bit lines b0, b2, and b3 and a positive potential is applied to the bit lines b1, b4, and b5. In addition, a zero potential is applied to the word lines w0, w2, w3, w4, w6, w7, w8, w9, and w10 and a negative potential is applied to the word lines w1, w5, and w11.

Accordingly, the two memory cells, L1 and L14, are simultaneously selected and a set operation or a sense operation is performed. At this point, since each current pathway is independent and a zero potential is applied to at least one of bit lines and word lines of unselected memory cells, there is no effect due to a snapback.

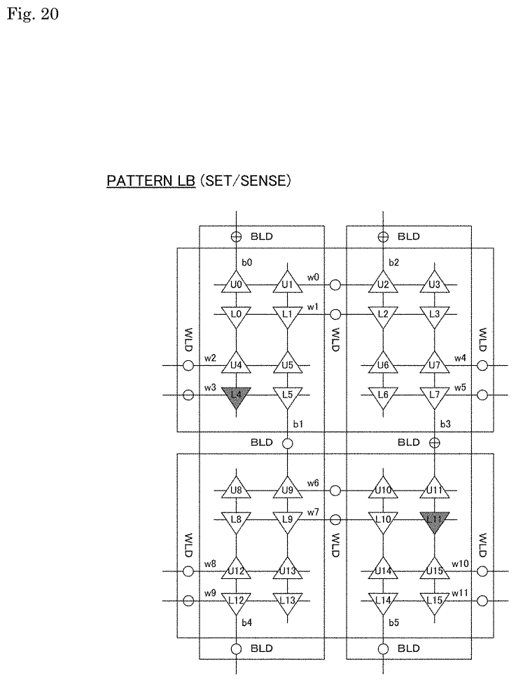

FIG. 20 is a diagram showing a second pattern example (a pattern LB) of applied voltage during a set operation or a sense operation of the lower-layer memory cell 112 according to the first embodiment of the present technique.

In the pattern LB, a zero potential is applied to the bit lines b1, b4, and b5 and a positive potential is applied to the bit lines b0, b2, and b3. In addition, a zero potential is applied to the word lines w0, w1, w2, w4, w5, w6, w8, w10, and w11 and a negative potential is applied to the word lines w3, w7, and w9.

Accordingly, the two memory cells, L4 and L11, are simultaneously selected and a set operation or a sense operation is performed. At this point, since each current pathway is independent and a zero potential is applied to at least one of bit lines and word lines of unselected memory cells, there is no effect due to a snapback.

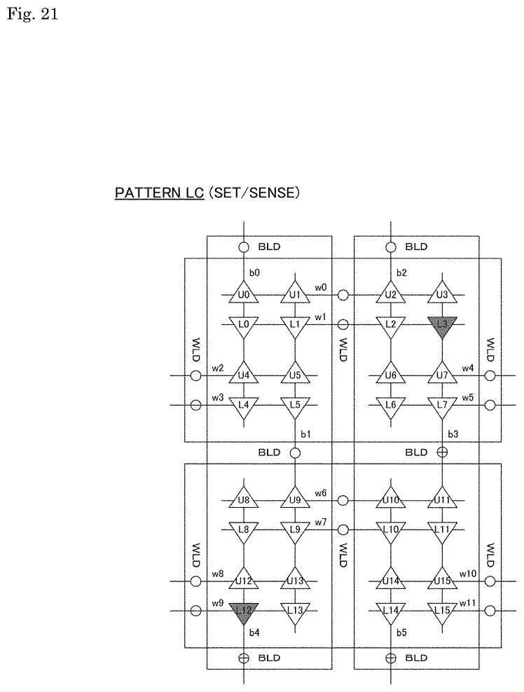

FIG. 21 is a diagram showing a third pattern example (a pattern LC) of applied voltage during a set operation or a sense operation of the lower-layer memory cell 112 according to the first embodiment of the present technique.

In the pattern LC, a zero potential is applied to the bit lines b0, b1, and b2 and a positive potential is applied to the bit lines b3, b4, and b5. In addition, a zero potential is applied to the word lines w0, w2, w4, w5, w6, w7, w8, w10, and w11 and a negative potential is applied to the word lines w1, w3, and w9.

Accordingly, the two memory cells, L3 and L12, are simultaneously selected and a set operation or a sense operation is performed. At this point, since each current pathway is independent and a zero potential is applied to at least one of bit lines and word lines of unselected memory cells, there is no effect due to a snapback.

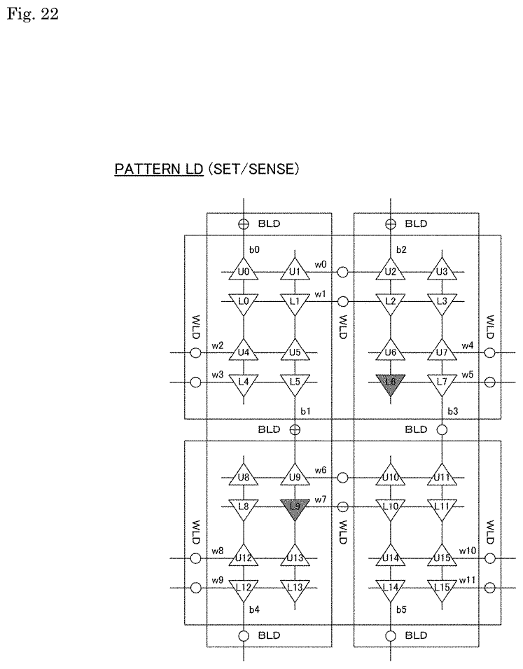

FIG. 22 is a diagram showing a fourth pattern example (a pattern LD) of applied voltage during a set operation or a sense operation of the lower-layer memory cell 112 according to the first embodiment of the present technique.

In the pattern LD, a zero potential is applied to the bit lines b3, b4, and b5 and a positive potential is applied to the bit lines b0, b1, and b2. In addition, a zero potential is applied to the word lines w0, w1, w2, w3, w4, w6, w8, w9, and w10 and a negative potential is applied to the word lines w5, w7, and w11.

Accordingly, the two memory cells, L6 and L9, are simultaneously selected and a set operation or a sense operation is performed. At this point, since each current pathway is independent and a zero potential is applied to at least one of bit lines and word lines of unselected memory cells, there is no effect due to a snapback.

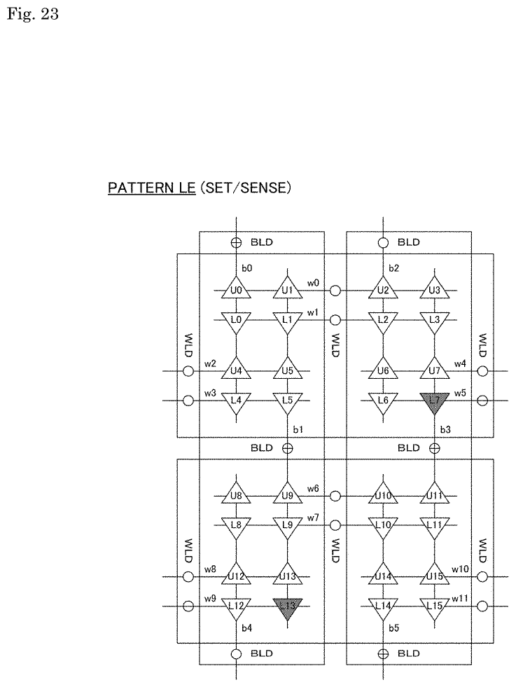

FIG. 23 is a diagram showing a fifth pattern example (a pattern LE) of applied voltage during a set operation or a sense operation of the lower-layer memory cell 112 according to the first embodiment of the present technique.

In the pattern LE, a zero potential is applied to the bit lines b2 and b4 and a positive potential is applied to the bit lines b0, b1, b3, and b5. In addition, a zero potential is applied to the word lines w0, w1, w2, w3, w4, w6, w7, w8, w10, and w11 and a negative potential is applied to the word lines w5 and w9.

Accordingly, the two memory cells, L7 and L13, are simultaneously selected and a set operation or a sense operation is performed. At this point, since each current pathway is independent and a zero potential is applied to at least one of bit lines and word lines of unselected memory cells, there is no effect due to a snapback.

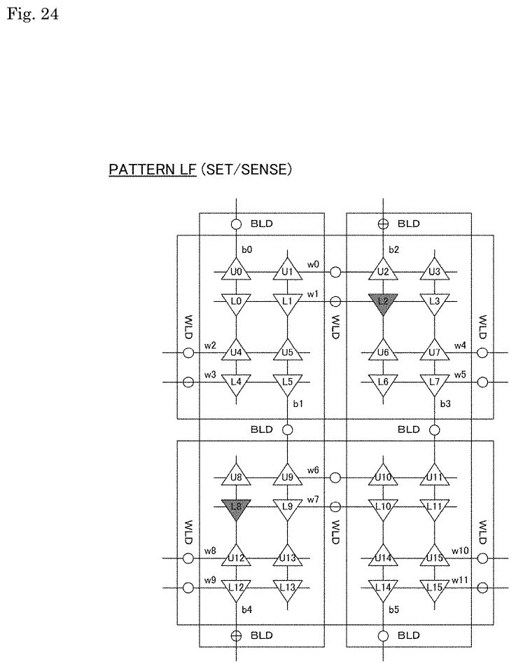

FIG. 24 is a diagram showing a sixth pattern example (a pattern LF) of applied voltage during a set operation or a sense operation of the lower-layer memory cell 112 according to the first embodiment of the present technique.

In the pattern LF, a zero potential is applied to the bit lines b0, b1, b3, and b5 and a positive potential is applied to the bit lines b2 and b4. In addition, a zero potential is applied to the word lines w0, w2, w4, w5, w6, w8, w9, and w10 and a negative potential is applied to the word lines w1, w3, w7, and w11.

Accordingly, the two memory cells, L2 and L8, are simultaneously selected and a set operation or a sense operation is performed. At this point, since each current pathway is independent and a zero potential is applied to at least one of bit lines and word lines of unselected memory cells, there is no effect due to a snapback.

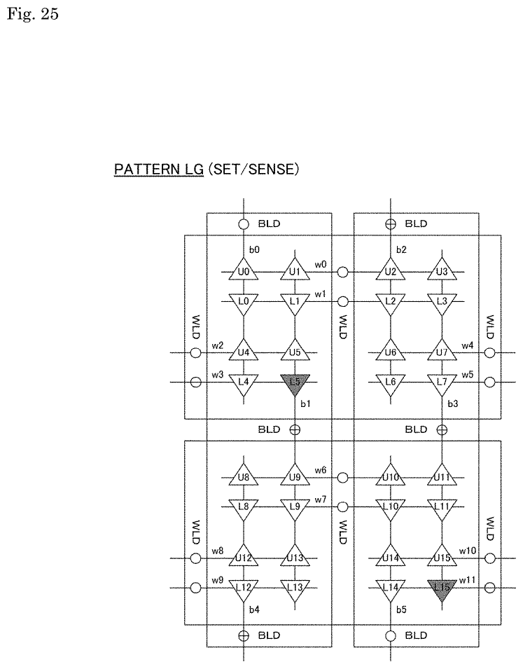

FIG. 25 is a diagram showing a seventh pattern example (a pattern LG) of applied voltage during a set operation or a sense operation of the lower-layer memory cell 112 according to the first embodiment of the present technique.

In the pattern LG, a zero potential is applied to the bit lines b0 and b5 and a positive potential is applied to the bit lines b1, b2, b3, and b4. In addition, a zero potential is applied to the word lines w0, w1, w2, w4, w5, w6, w7, w8, w9, and w10 and a negative potential is applied to the word lines w3 and w11.

Accordingly, the two memory cells, L5 and L15, are simultaneously selected and a set operation or a sense operation is performed. At this point, since each current pathway is independent and a zero potential is applied to at least one of bit lines and word lines of unselected memory cells, there is no effect due to a snapback.

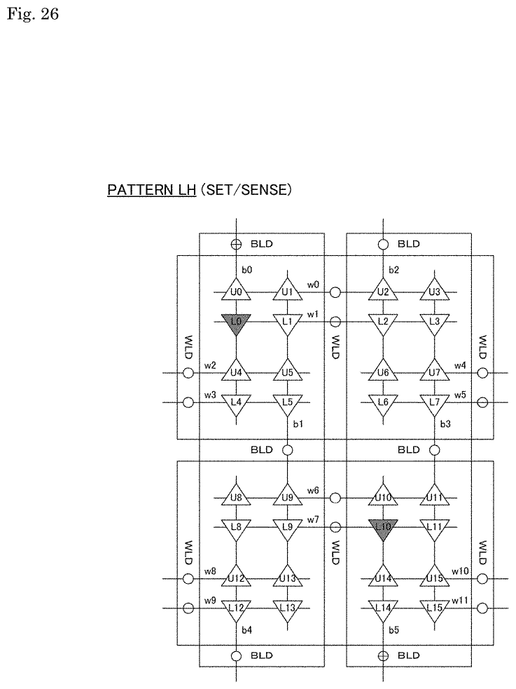

FIG. 26 is a diagram showing an eighth pattern example (a pattern LH) of applied voltage during a set operation or a sense operation of the lower-layer memory cell 112 according to the first embodiment of the present technique.

In the pattern LH, a zero potential is applied to the bit lines b1, b2, b3, and b4 and a positive potential is applied to the bit lines b0 and b5. In addition, a zero potential is applied to the word lines w0, w2, w3, w4, w6, w8, w10, and w11 and a negative potential is applied to the word lines w1, w5, w7, and w9.

Accordingly, the two memory cells, L0 and L10, are simultaneously selected and a set operation or a sense operation is performed. At this point, since each current pathway is independent and a zero potential is applied to at least one of bit lines and word lines of unselected memory cells, there is no effect due to a snapback.

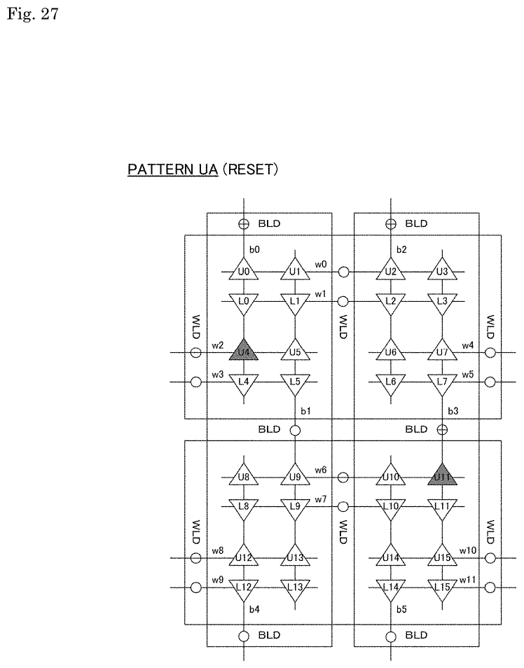

FIG. 27 is a diagram showing the first pattern example (the pattern UA) of applied voltage during a reset operation of the upper-layer memory cell 111 according to the first embodiment of the present technique.

In the pattern UA, a zero potential is applied to the bit lines b1, b4, and b5 and a positive potential is applied to the bit lines b0, b2, and b3. In addition, a zero potential is applied to the word lines w0, w1, w3, w4, w5, w7, w9, w10, and w11 and a negative potential is applied to the word lines w2, w6, and w8.

Accordingly, the two memory cells, U4 and U11, are simultaneously selected and a reset operation is performed. At this point, since each current pathway is independent and a zero potential is applied to at least one of bit lines and word lines of unselected memory cells, there is no effect due to a snapback.

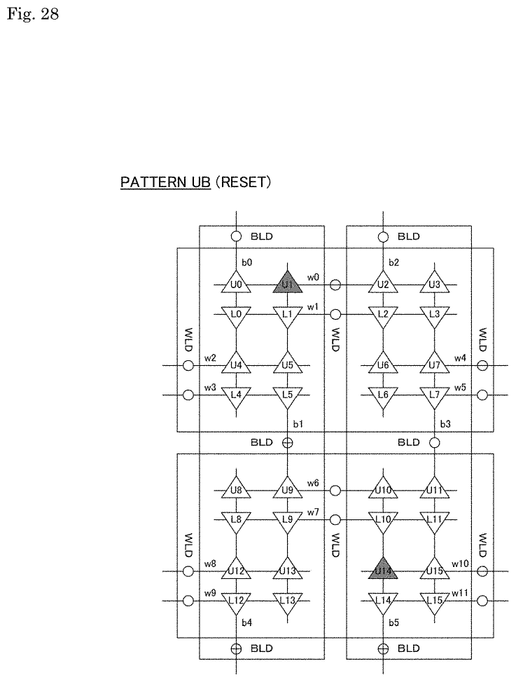

FIG. 28 is a diagram showing the second pattern example (the pattern UB) of applied voltage during a reset operation of the upper-layer memory cell 111 according to the first embodiment of the present technique.

In the pattern UB, a zero potential is applied to the bit lines b0, b2, and b3 and a positive potential is applied to the bit lines b1, b4, and b5. In addition, a zero potential is applied to the word lines w1, w2, w3, w5, w6, w7, w8, w9, and w11 and a negative potential is applied to the word lines w0, w4, and w10.

Accordingly, the two memory cells, U1 and U14, are simultaneously selected and a reset operation is performed. At this point, since each current pathway is independent and a zero potential is applied to at least one of bit lines and word lines of unselected memory cells, there is no effect due to a snapback.

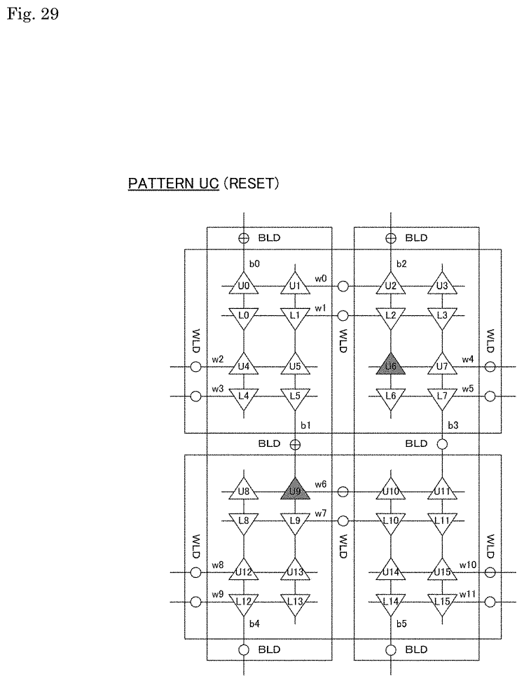

FIG. 29 is a diagram showing the third pattern example (the pattern UC) of applied voltage during a reset operation of the upper-layer memory cell 111 according to the first embodiment of the present technique.

In the pattern UC, a zero potential is applied to the bit lines b3, b4, and b5 and a positive potential is applied to the bit lines b0, b1, and b2. In addition, a zero potential is applied to the word lines w0, w1, w2, w3, w5, w7, w8, w9, and w11 and a negative potential is applied to the word lines w4, w6, and w10.

Accordingly, the two memory cells, U6 and U9, are simultaneously selected and a reset operation is performed. At this point, since each current pathway is independent and a zero potential is applied to at least one of bit lines and word lines of unselected memory cells, there is no effect due to a snapback.

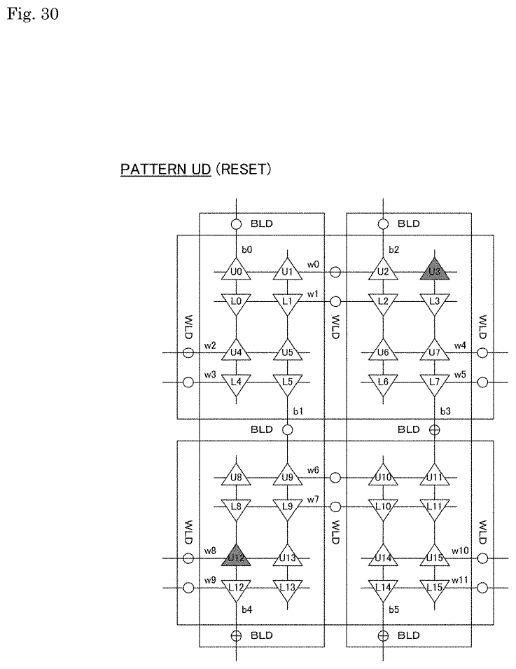

FIG. 30 is a diagram showing the fourth pattern example (the pattern UD) of applied voltage during a reset operation of the upper-layer memory cell 111 according to the first embodiment of the present technique.

In the pattern UD, a zero potential is applied to the bit lines b0, b1, and b2 and a positive potential is applied to the bit lines b3, b4, and b5. In addition, a zero potential is applied to the word lines w1, w3, w4, w5, w6, w7, w9, w10, and w11 and a negative potential is applied to the word lines w0, w2, and w8.

Accordingly, the two memory cells, U3 and U12, are simultaneously selected and a reset operation is performed. At this point, since each current pathway is independent and a zero potential is applied to at least one of bit lines and word lines of unselected memory cells, there is no effect due to a snapback.

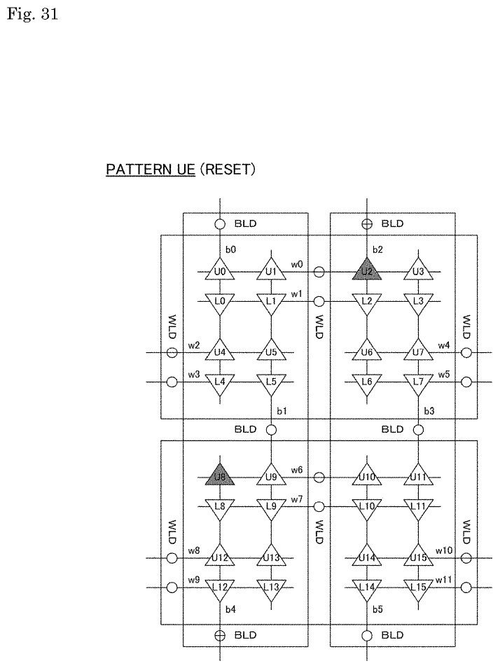

FIG. 31 is a diagram showing the fifth pattern example (the pattern UE) of applied voltage during a reset operation of the upper-layer memory cell 111 according to the first embodiment of the present technique.

In the pattern UE, a zero potential is applied to the bit lines b0, b1, b3, and b5 and a positive potential is applied to the bit lines b2 and b4. In addition, a zero potential is applied to the word lines w1, w3, w4, w5, w7, w8, w9, and w11 and a negative potential is applied to the word lines w0, w2, w6, and w10.

Accordingly, the two memory cells, U2 and U8, are simultaneously selected and a reset operation is performed. At this point, since each current pathway is independent and a zero potential is applied to at least one of bit lines and word lines of unselected memory cells, there is no effect due to a snapback.

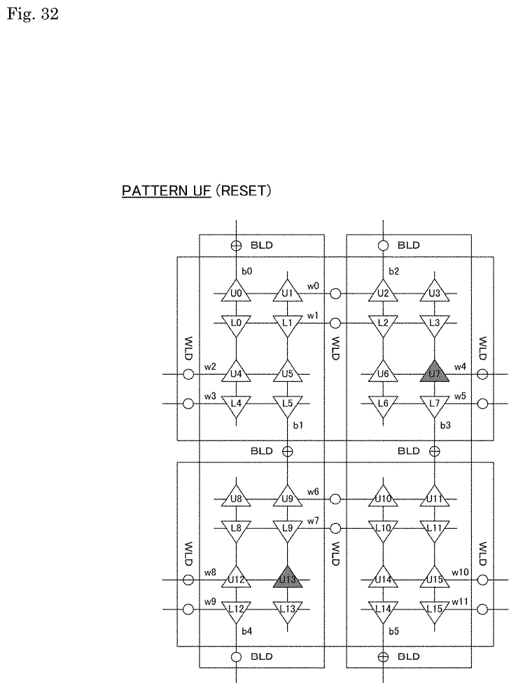

FIG. 32 is a diagram showing the sixth pattern example (the pattern UF) of applied voltage during a reset operation of the upper-layer memory cell 111 according to the first embodiment of the present technique.

In the pattern UF a zero potential is applied to the bit lines b2 and b4 and a positive potential is applied to the bit lines b0, b1, b3, and b5. In addition, a zero potential is applied to the word lines w0, w1, w2, w3, w5, w6, w7, w9, w10, and w11 and a negative potential is applied to the word lines w4 and w8.

Accordingly, the two memory cells, U7 and U13, are simultaneously selected and a reset operation is performed. At this point, since each current pathway is independent and a zero potential is applied to at least one of bit lines and word lines of unselected memory cells, there is no effect due to a snapback.

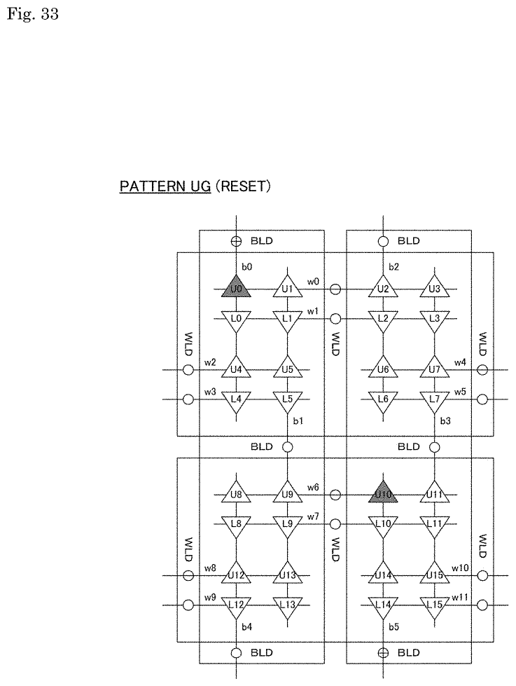

FIG. 33 is a diagram showing the seventh pattern example (the pattern UG) of applied voltage during a reset operation of the upper-layer memory cell 111 according to the first embodiment of the present technique.

In the pattern UG, a zero potential is applied to the bit lines b1, b2, b3, and b4 and a positive potential is applied to the bit lines b0 and b5. In addition, a zero potential is applied to the word lines w1, w2, w3, w5, w7, w9, w10, and w11 and a negative potential is applied to the word lines w0, w4, w6, and w8.

Accordingly, the two memory cells, U0 and U10, are simultaneously selected and a reset operation is performed. At this point, since each current pathway is independent and a zero potential is applied to at least one of bit lines and word lines of unselected memory cells, there is no effect due to a snapback.

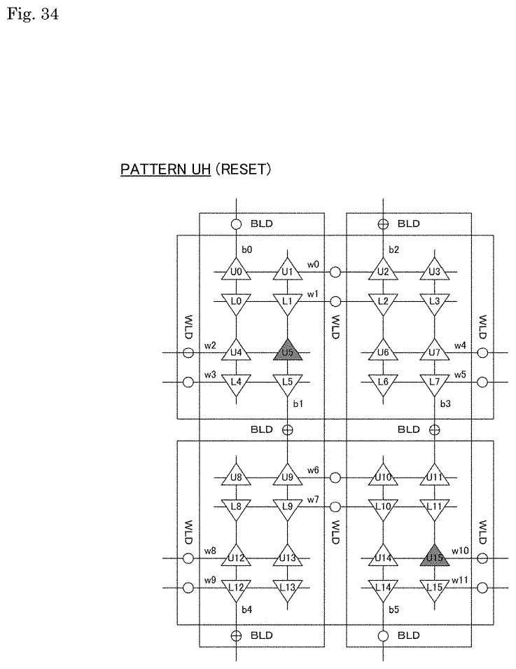

FIG. 34 is a diagram showing the eighth pattern example (the pattern UH) of applied voltage during a reset operation of the upper-layer memory cell 111 according to the first embodiment of the present technique.

In the pattern UH, a zero potential is applied to the bit lines b0 and b5 and a positive potential is applied to the bit lines b1, b2, b3, and b4. In addition, a zero potential is applied to the word lines w0, w1, w3, w4, w5, w6, w7, w8, w9, and w11 and a negative potential is applied to the word lines w2 and w10.

Accordingly, the two memory cells, U5 and U15, are simultaneously selected and a reset operation is performed. At this point, since each current pathway is independent and a zero potential is applied to at least one of bit lines and word lines of unselected memory cells, there is no effect due to a snapback.

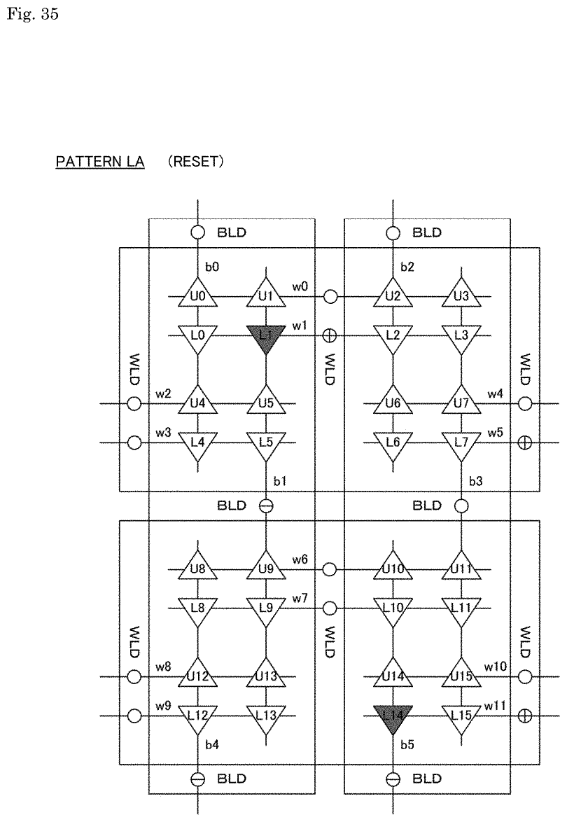

FIG. 35 is a diagram showing the first pattern example (the pattern LA) of applied voltage during a reset operation of the lower-layer memory cell 112 according to the first embodiment of the present technique.

In the pattern LA, a zero potential is applied to the bit lines b0, b2, and b3 and a negative potential is applied to the bit lines b1, b4, and b5. In addition, a zero potential is applied to the word lines w0, w2, w3, w4, w6, w7, w8, w9, and w10 and a positive potential is applied to the word lines w1, w5, and w11.

Accordingly, the two memory cells, L1 and L14, are simultaneously selected and a reset operation is performed. At this point, since each current pathway is independent and a zero potential is applied to at least one of bit lines and word lines of unselected memory cells, there is no effect due to a snapback.

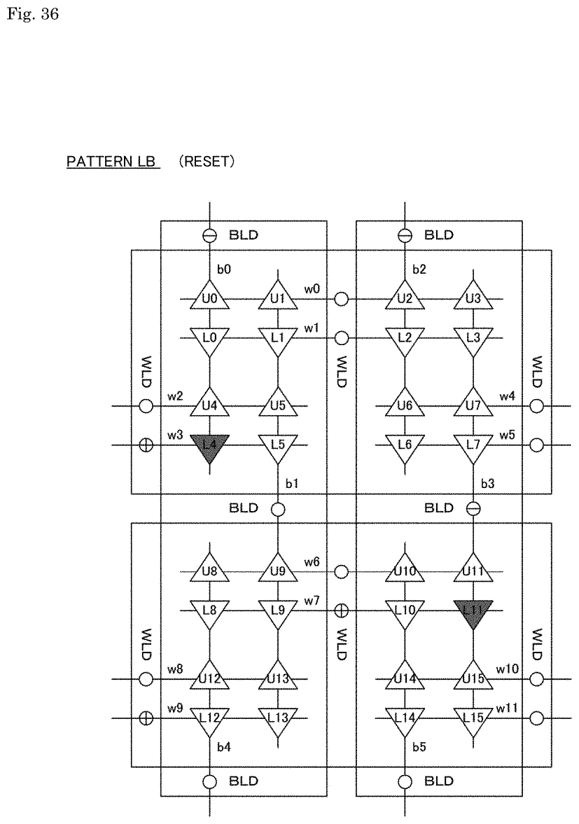

FIG. 36 is a diagram showing the second pattern example (the pattern LB) of applied voltage during a reset operation of the lower-layer memory cell 112 according to the first embodiment of the present technique.

In the pattern LB, a zero potential is applied to the bit lines b1, b4, and b5 and a negative potential is applied to the bit lines b0, b2, and b3. In addition, a zero potential is applied to the word lines w0, w1, w2, w4, w5, w6, w8, w10, and w11 and a positive potential is applied to the word lines w3, w7, and w9.

Accordingly, the two memory cells, L4 and L11, are simultaneously selected and a reset operation is performed. At this point, since each current pathway is independent and a zero potential is applied to at least one of bit lines and word lines of unselected memory cells, there is no effect due to a snapback.

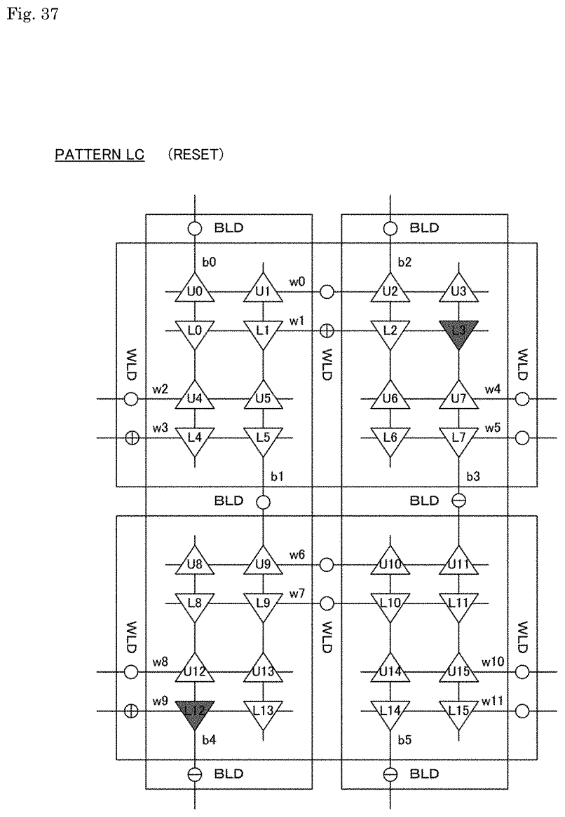

FIG. 37 is a diagram showing the third pattern example (the pattern LC) of applied voltage during a reset operation of the lower-layer memory cell 112 according to the first embodiment of the present technique.

In the pattern LC, a zero potential is applied to the bit lines b0, b1, and b2 and a negative potential is applied to the bit lines b3, b4, and b5. In addition, a zero potential is applied to the word lines w0, w2, w4, w5, w6, w7, w8, w10, and w11 and a positive potential is applied to the word lines w1, w3, and w9.

Accordingly, the two memory cells, L3 and L12, are simultaneously selected and a reset operation is performed. At this point, since each current pathway is independent and a zero potential is applied to at least one of bit lines and word lines of unselected memory cells, there is no effect due to a snapback.

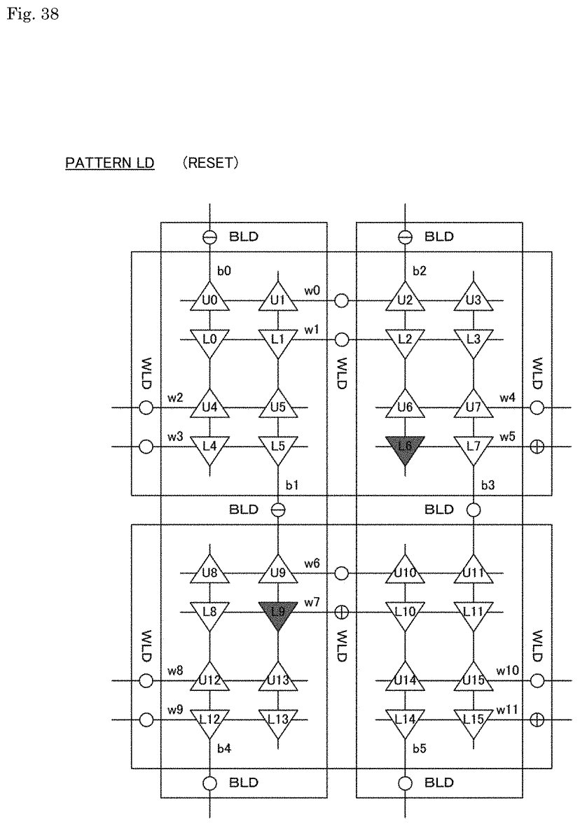

FIG. 38 is a diagram showing the fourth pattern example (the pattern LD) of applied voltage during a reset operation of the lower-layer memory cell 112 according to the first embodiment of the present technique.

In the pattern LD, a zero potential is applied to the bit lines b3, b4, and b5 and a negative potential is applied to the bit lines b0, b1, and b2. In addition, a zero potential is applied to the word lines w0, w1, w2, w3, w4, w6, w8, w9, and w10 and a positive potential is applied to the word lines w5, w7, and w11.

Accordingly, the two memory cells, L6 and L9, are simultaneously selected and a reset operation is performed. At this point, since each current pathway is independent and a zero potential is applied to at least one of bit lines and word lines of unselected memory cells, there is no effect due to a snapback.

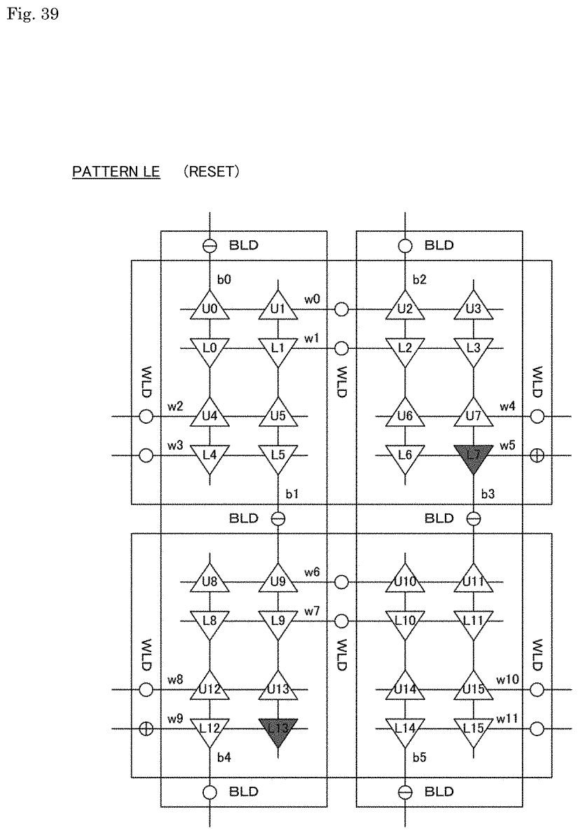

FIG. 39 is a diagram showing the fifth pattern example (the pattern LE) of applied voltage during a reset operation of the lower-layer memory cell 112 according to the first embodiment of the present technique.

In the pattern LE, a zero potential is applied to the bit lines b2 and b4 and a negative potential is applied to the bit lines b0, b1, b3, and b5. In addition, a zero potential is applied to the word lines w0, w1, w2, w3, w4, w6, w7, w8, w10, and w11 and a positive potential is applied to the word lines w5 and w9.

Accordingly, the two memory cells, L7 and L13, are simultaneously selected and a reset operation is performed. At this point, since each current pathway is independent and a zero potential is applied to at least one of bit lines and word lines of unselected memory cells, there is no effect due to a snapback.

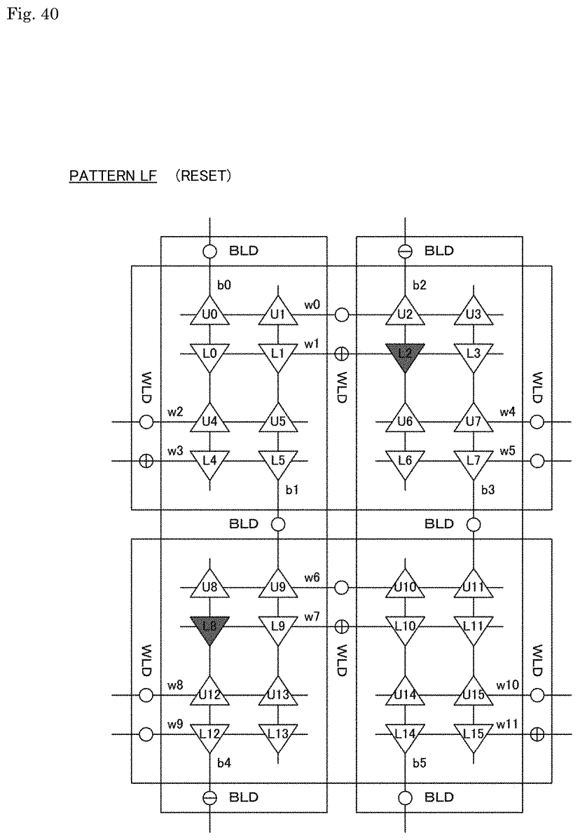

FIG. 40 is a diagram showing the sixth pattern example (the pattern LF) of applied voltage during a reset operation of the lower-layer memory cell 112 according to the first embodiment of the present technique.

In the pattern LF, a zero potential is applied to the bit lines b0, b1, b3, and b5 and a negative potential is applied to the bit lines b2 and b4. In addition, a zero potential is applied to the word lines w0, w2, w4, w5, w6, w8, w9, and w10 and a positive potential is applied to the word lines w1, w3, w7, and w11.

Accordingly, the two memory cells, L2 and L8, are simultaneously selected and a reset operation is performed. At this point, since each current pathway is independent and a zero potential is applied to at least one of bit lines and word lines of unselected memory cells, there is no effect due to a snapback.

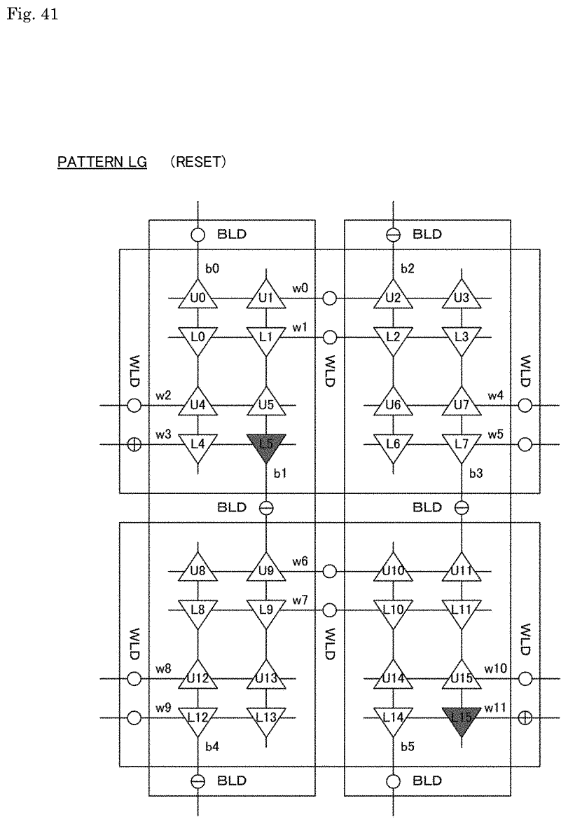

FIG. 41 is a diagram showing the seventh pattern example (the pattern LG) of applied voltage during a reset operation of the lower-layer memory cell 112 according to the first embodiment of the present technique.

In the pattern LG, a zero potential is applied to the bit lines b0 and b5 and a negative potential is applied to the bit lines b1, b2, b3, and b4. In addition, a zero potential is applied to the word lines w0, w1, w2, w4, w5, w6, w7, w8, w9, and w10 and a positive potential is applied to the word lines w3 and w11.

Accordingly, the two memory cells, L5 and L15, are simultaneously selected and a reset operation is performed. At this point, since each current pathway is independent and a zero potential is applied to at least one of bit lines and word lines of unselected memory cells, there is no effect due to a snapback.

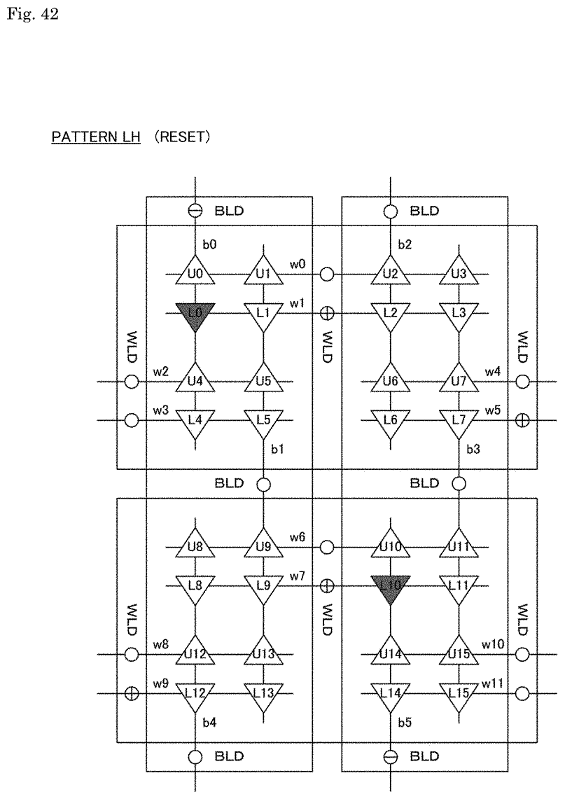

FIG. 42 is a diagram showing the eighth pattern example (the pattern LH) of applied voltage during a reset operation of the lower-layer memory cell 112 according to the first embodiment of the present technique.

In the pattern LH, a zero potential is applied to the bit lines b1, b2, b3, and b4 and a negative potential is applied to the bit lines b0 and b5. In addition, a zero potential is applied to the word lines w0, w2, w3, w4, w6, w8, w10, and w11 and a positive potential is applied to the word lines w1, w5, w7, and w9.

Accordingly, the two memory cells, L0 and L10, are simultaneously selected and a reset operation is performed. At this point, since each current pathway is independent and a zero potential is applied to at least one of bit lines and word lines of unselected memory cells, there is no effect due to a snapback.

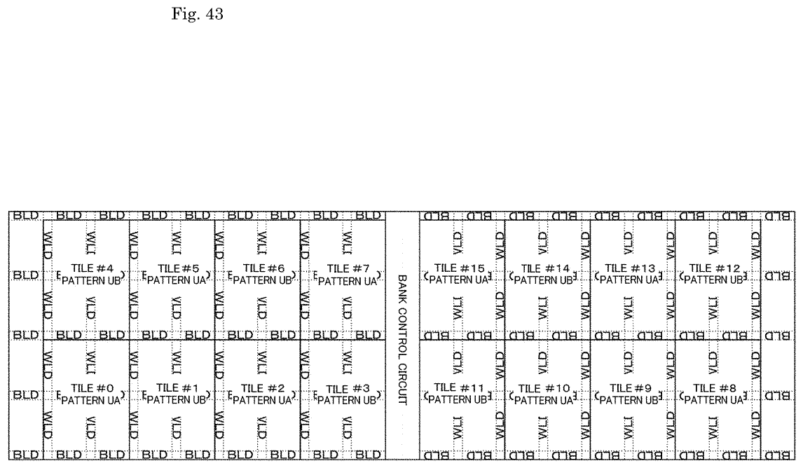

FIG. 43 is a diagram showing an arrangement example of patterns of applied voltage according to the embodiment of the present technique.

The respective patterns during the set operation or the sense operation and during the reset operation described above are used in combination so as to impart different polarities to adjacent tiles. For example, as shown in FIG. 43, the pattern UA is used in tiles #0, #2, #5, #7, #8, #10, #13, and #15, and the pattern UB is used in the other tiles #1, #3, #4, #6, #9, #11, #12, and #14. Accordingly, two memory cells can be simultaneously accessed in each tile while coordinating with the bit line decoder 220 and the word line decoder 230 of adjacent tiles.

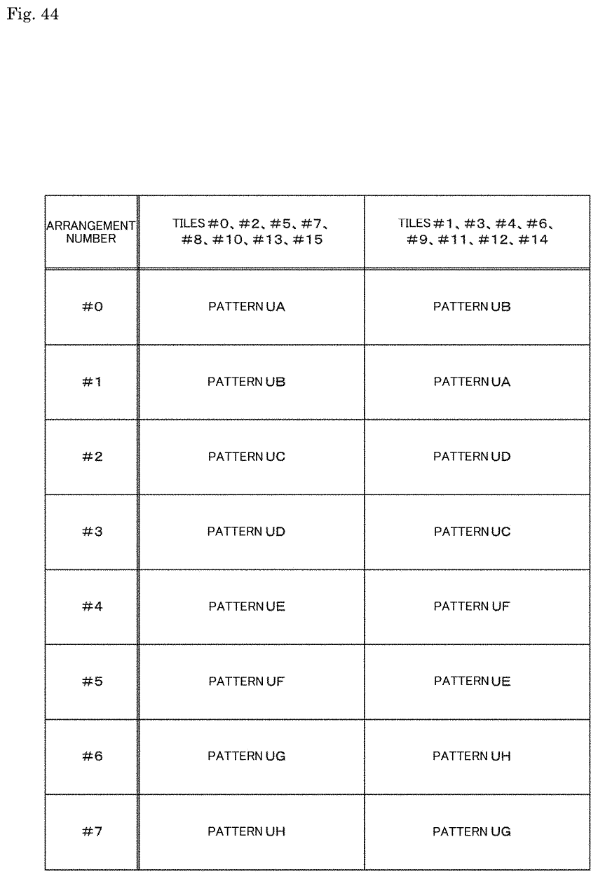

FIG. 44 is a diagram showing combination examples of arrangements of patterns of applied voltage according to the embodiment of the present technique.

An arrangement number #0 represents the example described above in which the pattern UA is used in tiles #0, #2, #5, #7, #8, #10, #13, and #15 and the pattern UB is used in the other tiles #1, #3, #4, #6, #9, #11, #12, and #14. In addition, an arrangement number #1 represents an example in which the pattern UA and the pattern UB of the arrangement number #0 have been swapped.

In a similar manner, arrangement numbers #2 and #3 respectively represent arrangements in which the pattern UC and the pattern UD have been swapped, arrangement numbers #4 and #5 respectively represent arrangements in which the pattern UE and the pattern UF have been swapped, and arrangement numbers #6 and #7 respectively represent arrangements in which the pattern UG and the pattern UH have been swapped.

Due to a total of eight pattern arrangements described above, two of all upper-layer memory cells 111 can be simultaneously accessed without duplication in each tile.

Patterns using the lower-layer memory cells 112 can be combined in a similar manner, and even when the patterns UA to UH are swapped with the patterns LA to LH, a total of eight pattern arrangements enable two of all lower-layer memory cell 112 can be simultaneously accessed without duplication in each tile.

In these patterns, the bit line decoder 220 supplies each bit line with a first voltage having any of positive and negative polarities or a zero potential. Specifically, for example, +3 V or −3 V is the first voltage in the set operation and the reset operation and +2 V or −2 V is the first voltage in the sense operation.

On the other hand, the word line decoder 230 supplies a second voltage of which a polarity has been reversed from the first voltage to one of the word lines intersecting the bit line supplied with the first voltage. In other words, for example, when +3 V is supplied as the first voltage, −3 V is the second voltage. In addition, the word line decoder 230 supplies a zero potential to the remaining word lines (word lines not supplied with the second voltage). Accordingly, only one memory cell is to be selected on a same bit line and a same word line and an independent current pathway can be secured. On the other hand, since a zero potential is applied to at least one of bit lines and word lines of unselected memory cells, an effect due to a snapback can be avoided.

[Address Signal]

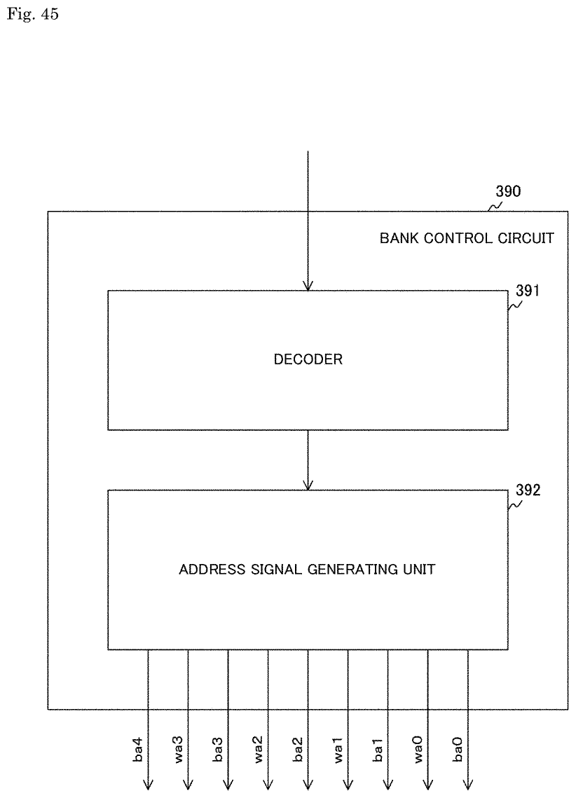

FIG. 45 is a diagram showing a configuration example of the bank control circuit 390 according to the embodiment of the present technique.

The bank control circuit 390 is provided with a decoder 391 and an address signal generating unit 392. The decoder 391 is a circuit that decodes an address of a command issued by the host computer 500.

The address signal generating unit 392 generates an address signal in accordance with a decoding result by the decoder 391. In this example, five bit line address signals ba0 to ba4 and four word line address signals wa0 to wa3 are supplied via each address line.

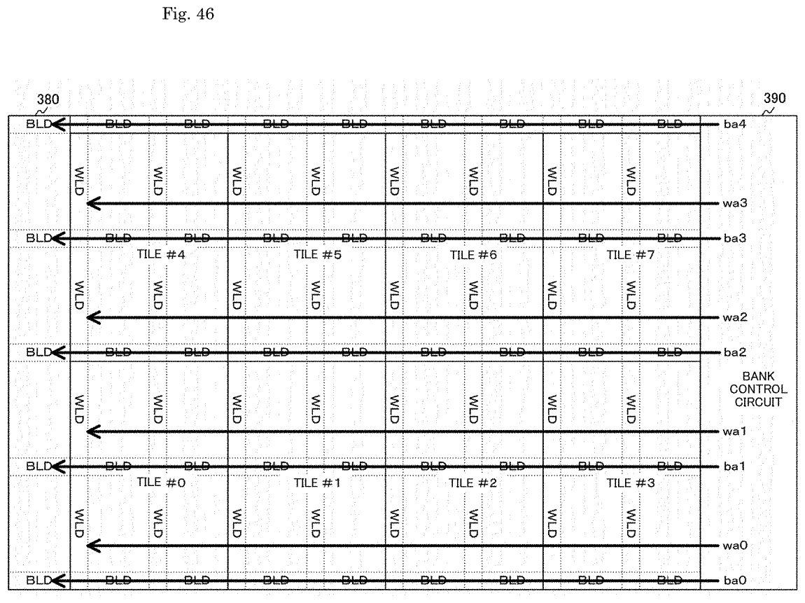

FIG. 46 is a diagram showing an arrangement example of address lines for supplying an address signal from the bank control circuit 390 according to the embodiment of the present technique.

As described earlier, the bank control circuit 390 is arranged at a center of the memory bank 310. The bank control circuit 390 supplies the bit line address signals ba0 to ba4 and the word line address signals wa0 to wa3 to the bit line decoder 220 and the word line decoder 230 arranged to the left and right.

The bit line address signals and the word line address signals are shared between left and right tiles. In addition, the bit line address signals are also supplied to the edge block 380.

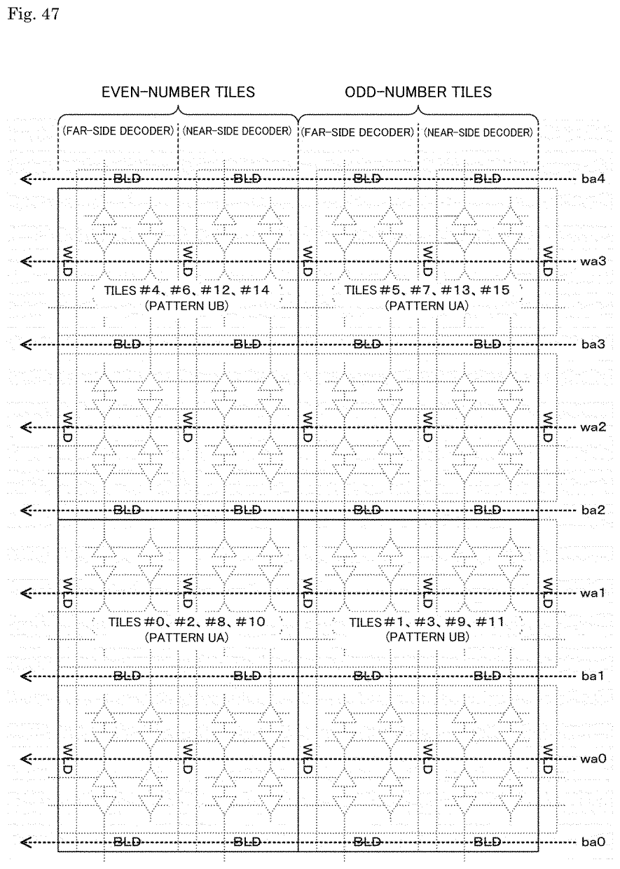

FIG. 47 is a diagram showing an example of names of address signals supplied from the bank control circuit 390 according to the embodiment of the present technique.

In this example, assuming that the bank control circuit 390 is arranged to the right, even-number tiles are shown on a left side and off-number tiles are shown on a right side.

In each tile, a same bit line address signal and a same word line address signal are supplied to two bit line decoders 220 and two word line decoders 230. At this point, a distinction will be made by referring to whichever is closer to the bank control circuit 390 as a near-side and whichever is farther from the bank control circuit 390 as a far-side.

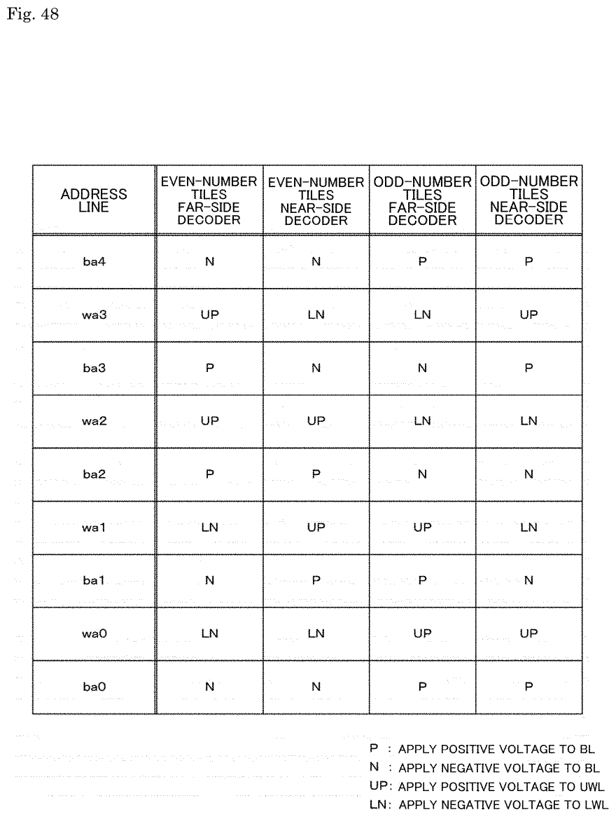

FIG. 48 is a diagram showing an example of contents of address signals supplied from the bank control circuit 390 according to the embodiment of the present technique.

Each of the bit line address signals ba0 to ba4 indicates a polarity of a voltage to be applied to the bit lines. For example, a bit line address signal of “P” indicates that a positive voltage will be applied to the bit lines. On the other hand, a bit line address signal of “N” indicates that a negative voltage will be applied to the bit lines.

Each of the word line address signals wa0 to wa3 represents information indicating which of the upper word lines 131 and the lower word lines 132 are to be an object and information indicating a polarity of a voltage to be applied to the word lines. For example, a word line address signal of “UP” indicates that a positive voltage will be applied to the upper word lines 131. On the other hand, a word line address signal of “LN” indicates that a negative voltage will be applied to the lower word lines 132.

[Sense Amplifier]

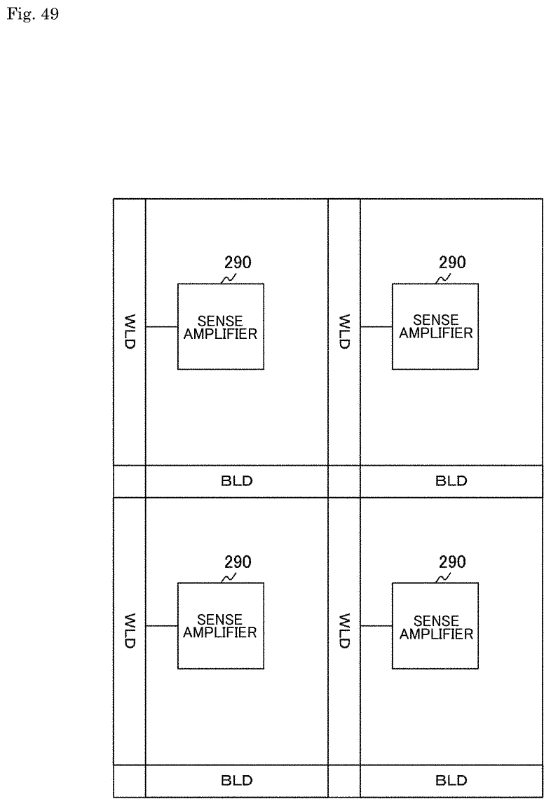

FIG. 49 is a diagram showing an arrangement example of a sense amplifier 290 according to the embodiment of the present technique.

A read in a cross point memory can be performed on both word lines and bit lines. However, a read is desirably performed on whichever parasitic capacitance is smaller. In other words, from the perspective of speed, the smaller the capacitance, the higher the speed of detection of a current or a voltage of a memory cell. In addition, in terms of a lifetime of a memory cell, electric charges stored in the parasitic capacitance flows through the memory cell during each read and may cause degradation.

In the present embodiment, since word lines are only connected to memory cells of one layer but bit lines are shared between memory cells of two layers, word lines have a smaller parasitic capacitance. Therefore, in the present embodiment, the sense amplifier 290 is connected to the word lines.

In addition, although four sense amplifiers 290 are to be provided per tile with respect to a configuration in which two bits are simultaneously read per tile, this is not a waste. For example, when focusing on the word line decoder 230 to which certain tiles belong, a situation may occur in which 4 bits are read in two tiles as a result of 1 bit being read in one tile and 3 bits being read in the other tile. Therefore, while there are cases where a simultaneous read of 2 bits cannot be performed with two sense amplifiers 290 per tile, this can be solved by providing four sense amplifiers 290 per tile.

In addition, distances between the sense amplifier 290 and word lines are desirably short because the shorter the distances, the smaller the parasitic capacitance of wires. Therefore, as shown in the drawings, the sense amplifier 290 is desirably arranged in a vicinity of the word line decoder 230.

It should be noted that, when taking withstand voltage constraints of a gate voltage of a transistor into consideration, different sense amplifiers 290 are desirably provided between an upper layer and a lower layer of a two-layer cross point memory. Therefore, the number of sense amplifiers 290 in this case is eight per tile.

As described above, according to the first embodiment of the present technique, by securing an independent current pathway due to a voltage supplied from the bit line decoder 220 and the word line decoder 230, two memory cells can be simultaneously selected and accessed in each tile. Accordingly, power consumption can be reduced by increasing parallelism of accesses in a cross point memory while avoiding an unauthorized access attributable to a snapback.

### 2. SECOND EMBODIMENT

While a two-layer memory array is assumed in the first embodiment described above, the present technique can also be applied to a single-layer memory array. In a second embodiment, an application example to a single-layer memory array will be described. Since premises with respect to the overall configuration of the storage apparatus 300 and the resistance random access memory cell 10 are similar to those of the first embodiment described above, a detailed description thereof will be omitted.

[Voltage application pattern]

In the second embodiment, 16 memory cells 10 in a tile will be distinguished as U0 to U15. Furthermore, the word lines in a tile and straddling tiles are distinguished as word lines w0, w2, w4, w6, w8, and w10 and the bit lines 120 in the tile and straddling tiles are distinguished as bit lines b0 to b5.

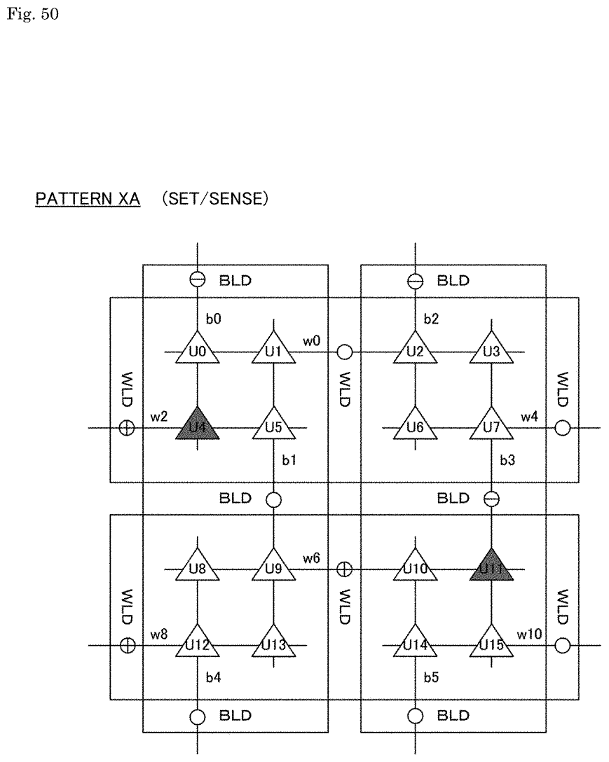

FIG. 50 is a diagram showing a first pattern example (a pattern XA) of applied voltage during a set operation or a sense operation according to the second embodiment of the present technique.

In the pattern XA, a negative potential is applied to the bit lines b0, b2, and b3 and a zero potential is applied to the bit lines b1, b4, and b5. In addition, a zero potential is applied to the word lines w0, w4, and w10 and a positive potential is applied to the word lines w2, w6, and w8.

Accordingly, the two memory cells, U4 and U11, are simultaneously selected and a set operation or a sense operation is performed. At this point, since each current pathway is independent and a zero potential is applied to at least one of bit lines and word lines of unselected memory cells, there is no effect due to a snapback.

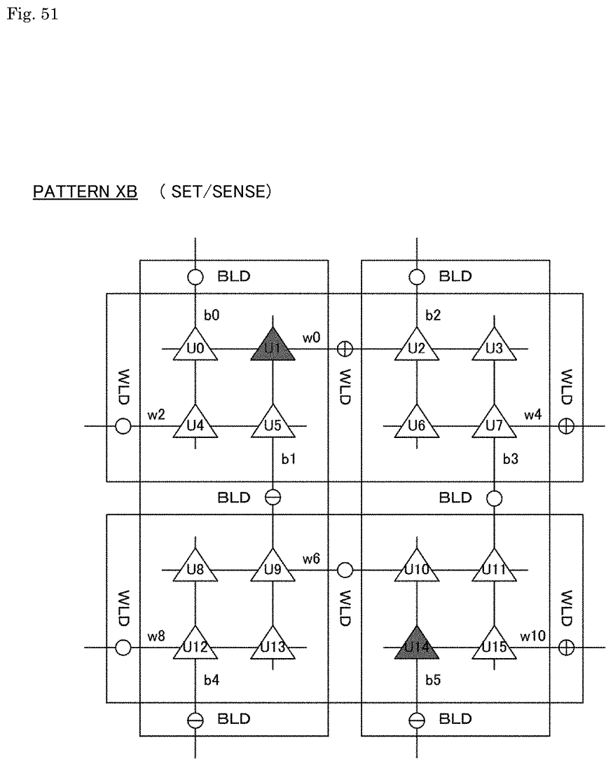

FIG. 51 is a diagram showing a second pattern example (a pattern XB) of applied voltage during a set operation or a sense operation according to the second embodiment of the present technique.

In the pattern XB, a negative potential is applied to the bit lines b1, b4, and b5 and a zero potential is applied to the bit lines b0, b2, and b3. In addition, a zero potential is applied to the word lines w2, w6, and w8 and a positive potential is applied to the word lines w0, w4, and w10.

Accordingly, the two memory cells, U1 and U14, are simultaneously selected and a set operation or a sense operation is performed. At this point, since each current pathway is independent and a zero potential is applied to at least one of bit lines and word lines of unselected memory cells, there is no effect due to a snapback.

The patterns XA and XB of applied voltage during a set operation or a sense operation described above are equivalent to extracting only the upper-layer memory cells 111 from the patterns UA and UB in the first embodiment described earlier. Therefore, the pattern XA can be used in tiles #0, #2, #5, #7, #8, #10, #13, and #15 and the pattern XB can be used in the other tiles #1, #3, #4, #6, #9, #11, #12, and #14. In addition, an arrangement in which the pattern XA and the pattern XB are swapped may be adopted. In this manner, by combining arrangements of the patterns of applied voltage described above, two memory cells can be simultaneously accessed in each tile while coordinating with the bit line decoder 220 and the word line decoder 230 of adjacent tiles.

In addition, patterns XC to XII created by extracting only the upper-layer memory cells 111 from the patterns UC to UH can be combined in a similar manner. Accordingly, due to a total of eight pattern arrangements, two of all upper-layer memory cells 111 can be simultaneously accessed without duplication in each tile.

Furthermore, while examples in which only the upper-layer memory cells 111 are extracted have been described above, alternatively, only the lower-layer memory cells 112 may be extracted and combined in a similar manner. Accordingly, due to a total of eight pattern arrangements, two of all lower-layer memory cells 112 can be simultaneously accessed without duplication in each tile.

While patterns of applied voltage during a set operation or a sense operation have been described in the above examples, the description similarly applies to patterns of applied voltage during a reset operation with the only difference being their polarities reversed.

As described above, according to the second embodiment of the present technique, even with single-layer memory arrays, by securing an independent current pathway due to a voltage supplied from the bit line decoder 220 and the word line decoder 230, two memory cells can be simultaneously selected and accessed in each tile.

### 3. MODIFICATIONS

In the first embodiment described above, an example assuming a two-layer cross point memory sharing bit lines 120 has been explained. The present technique can also be applied as a modification to a three-layer cross point memory in which upper-layer bit lines are further stacked on top of the upper word lines 131 to form a third memory layer between the upper word lines 131 and the upper-layer bit lines. In addition, the present technique can also be applied to a four-layer cross point memory in which third word lines are further stacked on top of the three-layer cross point memory. However, the number of bits that can be simultaneously selected in these cases remain the same as in the case of the two-layer cross point memory: 2 bits per tile.

Furthermore, as another modification, the present technique can also be applied to a four-layer cross point memory in which two two-layer cross point memories are stacked without sharing word lines. In this case, as a total of four layers, 4 bits can be simultaneously selected per tile.

The embodiments described above represent an example for embodying the present technique, and matters described in the embodiments and invention-defining manners described in the claims respectively correspond to each other. In a similar manner, the invention-defining manners described in the claims and matters described using same names in the embodiments of the present technique respectively correspond to each other. However, the present technique is not limited to the embodiments and the present technique can be embodied by making various modifications to the embodiments without departing from the gist of the technique.

The structures and characteristics of the memory cells 10 described in the above embodiments are merely examples and are not intended to limit the memory cells 10 as components of the present technique. For example, while variations such as those described below are conceivable, the present technique can be similarly applied to any of the following modifications. (a) In the embodiments described above, the directions of applied voltage are the same for set and sense but the directions of applied voltage are reversed between set and reset. Conversely, the directions of applied voltage may be reversed between set and sense and the directions of applied voltage may be the same for reset and sense. In addition, memory cells in which the directions of applied voltage are the same for set, reset, and sense may be used. Such a memory cell is generally referred to as a unipolar memory cell. (b) While the memory cell 10 has a series structure of the variable resistor 11 and the selector 12 in the embodiments described above, alternatively, the memory cell 10 may be constituted by a single element having both variable resistance characteristics and diode characteristics. (c) The present technique can be applied to the memory cell 10 regardless of an operating principle or a material composition thereof as long as the memory cell 10 is a structure including a variable resistance element in a broad sense. Examples of the variable resistance element in a broad sense include a phase-change memory (PCM), a magnetoresistive random access memory (MRAM), a ferroelectric random access memory (FeRAM), a spin-transfer torque random access memory (STT-RAM), and a carbon nanotube random access memory (CBRAM).

The advantageous effects described in the present specification are merely exemplary and are not restrictive, and other advantageous effects may be produced.

The present technique can also be configured as follows.

(1)

A storage apparatus, including:

a storage unit provided with a plurality of first wires extending in a first direction, a plurality of second wires extending in a second direction that differs from the first direction, and a plurality of memory cells inserted and installed at a position where any of the plurality of first wires and any of the plurality of second wires intersect with each other;
a plurality of first driving units configured to supply a first voltage having any of a positive polarity and a negative polarity or a zero potential to each of the plurality of first wires; and
a plurality of second driving units configured to supply a second voltage with a different polarity from the first voltage to any one of the plurality of second wires intersecting a first wire to which the first voltage is supplied among the plurality of first wires and configured to supply a zero potential to a remainder of the plurality of second wires intersecting the plurality of first wires.
(2)

The storage apparatus according to (1) described above, wherein the plurality of first driving units are provided for each of the plurality of memory cells which share one of the plurality of first wires, and the plurality of second driving units are provided for each of the plurality of memory cells which share one of the plurality of second wires.

(3)

The storage apparatus according to (1) or (2) described above, wherein when dividing the plurality of first driving units and the plurality of second driving units into a plurality of unit structures provided with a predetermined number of the plurality of first driving units and a predetermined number of the plurality of second driving units, voltage supply patterns with respect to the pluralities of the first and second wires differ from each other between adjacent unit structures among the plurality of unit structures.

(4)

The storage apparatus according to (3) described above, wherein the pluralities of first and second driving units at a boundary between adjacent unit structures among the plurality of unit structures are shared by the adjacent unit structures.

(5)

The storage apparatus according to any one of (1) to (4) described above, wherein the plurality of memory cells are provided with storage elements of which each assume any resistance state of first and second resistance states, and the storage elements are set to any of the first and second resistance states in accordance with a direction of a current that flows when voltages of mutually different polarities are applied to the first and second wires.

(6)

The storage apparatus according to any one of (1) to (5) described above, wherein the plurality of memory cells are provided with first and second storage elements which share one of the plurality of first wires.

(7)

The storage apparatus according to (6) described above, wherein the plurality of second driving units are configured to supply a voltage of a zero potential to the second wire of one of the first and second storage elements and to supply a voltage having one of a positive polarity and a negative polarity to the second wire of the other storage element.

(8)

The storage apparatus according to any one of (1) to (7) described above, further including

a plurality of sense amplifiers connected to the plurality of second wires so as to correspond to each of the plurality of second driving units.
(9)

The storage apparatus according to any one of (1) to (8) described above, further including

a control circuit configured to supply a control signal for instructing a polarity of a voltage to be applied to the pluralities of first and second wires to the pluralities of first and second driving units.
(10)

A storage control apparatus that controls a storage apparatus provided with a plurality of first wires extending in a first direction, a plurality of second wires extending in a second direction that differs from the first direction, and a plurality of memory cells inserted and installed at a position where any of the plurality of first wires and any of the plurality of second wires intersect with each other, the storage control apparatus including:

a plurality of first driving units configured to supply a first voltage having any of a positive polarity and a negative polarity or a zero potential to each of the plurality of first wires; and
a plurality of second driving units configured to supply a second voltage with a different polarity from the first voltage to any one of the plurality of second wires intersecting a first wire to which the first voltage is supplied among the plurality of first wires and configured to supply a zero potential to a remainder of the plurality of second wires intersecting the plurality of first wires.

### REFERENCE SIGNS LIST

10 Memory cell
11 Variable resistor
12 Selector
18 Upper terminal
19 Lower terminal
111 Upper-layer memory cell
112 Lower-layer memory cell
120 Bit line
131 Upper word line
132 Lower word line
220 Bit line decoder
230 Word line decoder
290 Sense amplifier
300 Storage apparatus
310 Memory bank
320 Tile
370 Peripheral region
371 Interface
380 Edge block
390 Bank control circuit
391 Decoder
392 Address signal generating unit
400 Memory controller
500 Host computer

What is claimed is:

1. A storage apparatus, comprising:
a storage unit provided with a plurality of first wires extending in a first direction, a plurality of second wires extending in a second direction that differs from the first direction, and a plurality of memory cells inserted and installed at a position where any of the plurality of first wires and any of the plurality of second wires intersect with each other;
a plurality of first driving units configured to supply a first voltage having any of a positive polarity and a negative polarity or a zero potential to each of the plurality of first wires; and
a plurality of second driving units configured to supply a second voltage with a different polarity from the first voltage to any one of the plurality of second wires intersecting a first wire to which the first voltage is supplied among the plurality of first wires and configured to supply a zero potential to a remainder of the plurality of second wires intersecting the plurality of first wires.

2. The storage apparatus according to claim 1, wherein
the plurality of first driving units are provided for each of the plurality of memory cells which share one of the plurality of first wires, and
the plurality of second driving units are provided for each of the plurality of memory cells which share one of the plurality of second wires.

3. The storage apparatus according to claim 1, wherein
when dividing the plurality of first driving units and the plurality of second driving units into a plurality of unit structures provided with a predetermined number of the plurality of first driving units and a predetermined number of the plurality of second driving units, voltage supply patterns with respect to the pluralities of the first and second wires differ from each other between adjacent unit structures among the plurality of unit structures.

4. The storage apparatus according to claim 3, wherein
the pluralities of first and second driving units at a boundary between adjacent unit structures among the plurality of unit structures are shared by the adjacent unit structures.

5. The storage apparatus according to claim 1, wherein
the plurality of memory cells are provided with storage elements of which each assume any resistance state of first and second resistance states, and
the storage elements are set to any of the first and second resistance states in accordance with a direction of a current that flows when voltages of mutually different polarities are applied to the first and second wires.

6. The storage apparatus according to claim 1, wherein
the plurality of memory cells are provided with first and second storage elements which share one of the plurality of first wires.

7. The storage apparatus according to claim 6, wherein
the plurality of second driving units are configured to supply a voltage of a zero potential to the second wire of one of the first and second storage elements and to supply a voltage having one of a positive polarity and a negative polarity to the second wire of the other storage element.

8. The storage apparatus according to claim 1, further comprising
a plurality of sense amplifiers connected to the plurality of second wires so as to correspond to each of the plurality of second driving units.

9. The storage apparatus according to claim 1, further comprising
a control circuit configured to supply a control signal for instructing a polarity of a voltage to be applied to the pluralities of first and second wires to the pluralities of first and second driving units.

10. A storage control apparatus that controls a storage apparatus provided with a plurality of first wires extending in a first direction, a plurality of second wires extending in a second direction that differs from the first direction, and a plurality of memory cells inserted and installed at a position where any of the plurality of first wires and any of the plurality of second wires intersect with each other, the storage control apparatus comprising:
a plurality of first driving units configured to supply a first voltage having any of a positive polarity and a negative polarity or a zero potential to each of the plurality of first wires; and
a plurality of second driving units configured to supply a second voltage with a different polarity from the first voltage to any one of the plurality of second wires intersecting a first wire to which the first voltage is supplied among the plurality of first wires and configured to supply a zero potential to a remainder of the plurality of second wires intersecting the plurality of first wires.
